(19) United States
(12) Patent Application Publication
(10) Pub. No.: US 2025/0191876 A1
(43) Pub. Date: Jun. 12, 2025

(54) STABLE ELECTRON MICROSCOPY SPECIMEN HOLDER OPERATING AT LOW TEMPERATURES

(71) Applicants: President and Fellows of Harvard College, Cambridge, MA (US); The Regents of the University of Michigan, Ann Arbor, MI (US)

(72) Inventors: Ismail EL BAGGARI, Cambridge, MA (US); Robert HOVDEN, Ann Arbor, MI (US); Emily J. RENNICH, Ann Arbor, MI (US)

(21) Appl. No.: 18/845,264

(22) PCT Filed: Mar. 8, 2023
(86) PCT No.: PCT/US2023/063942

§ 371 Date: Sep. 9, 2024

Related U.S. Application Data
(60) Provisional application No. 63/318,049, filed on Mar. 9, 2022.

(51) Int. Cl. H01J 37/20

(52) U.S. Cl. CPC H01J 37/20; H01J 2237/002

(57) ABSTRACT

In one aspect, a specimen holder includes a first end configured to attach to a cooling device and a second end configured to be inserted into a microscope; a section with a sample tip at the second end; an interface between the first end configured to attach to the cooling device and the section with the sample tip; and an internal thermal connection section configured to be in thermal contact with a cold finger of the cooling device when the specimen holder is attached to the cooling device and extending through the section with the sample tip to the sample tip.

### CROSS-REFERENCES TO RELATED APPLICATIONS

This patent application claims the benefit of U.S. Provisional Application No. 63/318,049, filed on Mar. 9, 2022, the contents of which are incorporated by reference herein in its entirety.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF THE INVENTION

The instant application relates to an electron microscopy specimen holder. In particular, the instant application relates to an electron microscopy specimen holder for operating at low temperatures.

### BACKGROUND OF THE TECHNOLOGY

Microscopy often benefits from keeping the specimens at low temperatures. For example, some specimens such as polymers, battery electrolytes and biological matter degrade under vacuum conditions or due to impact from electrons (e.g., during electron microscopy) or photons (e.g., during X-ray imaging). Cooling specimens preserves their structure by slowing or arresting pathways to degradation.

Other specimens are interesting to study and test at low temperatures. These include quantum materials and devices used for quantum computing, magnets, superconductors, batteries and other electronics for space applications, and materials relevant for scientific research in the quantum and energy fields.

Electron microscopes are kept at ambient temperatures, resulting in a large thermal gradient between the instrument and a cooled sample. As a result, cryogenic cooling has remained a challenge due to vibrations, thermal expansion, and drift. Additionally, electron microscopes have very limited sample space (a few millimeters). Temperatures lower than the boiling temperature of liquid nitrogen (77 K) are even more challenging. For example, liquid helium is difficult to use under limited space constraints.

### SUMMARY

In one aspect, a specimen holder includes a first end configured to attach to a cooling device and a second end configured to be inserted into a microscope; a section with a sample tip at the second end; an interface between the first end configured to attach to the cooling device and the section with the sample tip; and an internal thermal connection section configured to be in thermal contact with a cold finger of the cooling device when the specimen holder is attached to the cooling device and extending through the section with the sample tip to the sample tip.

In some embodiments, the specimen holder includes the cooling device.

In some embodiments, the cooling device is a cryostat.

In some embodiments, the cryostat is a flow cryostat, a closed-cycle cryostat, or a bath cryostat.

In some embodiments, the cryostat is a flow cryostat.

In some embodiments, the cooling device cools with a cryogenic liquid or a cryogenic gas.

In some embodiments, the cooling device cools with two or more different cryogenic liquids or cryogenic gases.

In some embodiments, the pressure of the cryogenic liquid or cryogenic gas is increased or decreased compared to atmosphere.

In some embodiments, the cryogenic liquid is selected from the group consisting of helium, nitrogen, hydrogen, neon, and a combination thereof.

In some embodiments, the cryogenic liquid is helium.

In some embodiments, the cryogenic liquid is nitrogen.

In some embodiments, the internal thermal section includes a flexible portion.

In some embodiments, the flexible portion is configured to be in thermal contact with the cold finger when the specimen holder is attached to the cooling device and extends through the section with the sample tip to the sample tip.

In some embodiments, the internal thermal connection includes the flexible portion configured to be in thermal contact with the cold finger when the specimen holder is attached to the cooling device; and a rigid portion in thermal contact with the flexible portion and extending through the section with the sample tip to the sample tip.

In some embodiments, the internal thermal connection is selected from a material consisting of copper, silver, aluminum, quartz sapphire, and a combination thereof.

In some embodiments, the internal thermal connection is plated with an inert metal.

In some embodiments, the flexible portion includes braids, sleeves, springs, wire bundles, straps, and a combination thereof.

In some embodiments, the specimen holder further includes one or more low thermal conductivity rings or pins disposed along the length of the section with the sample tip to support the internal thermal connection section.

In some embodiments, the specimen holder further includes netting or thermal insulation material to support the flexible portion of the thermal connection section.

In some embodiments, the specimen holder further includes a collar at the second end configured to rigidly connect the internal thermal connection section to the sample tip.

In some embodiments, the collar includes a low thermal conductivity material.

In some embodiments, the interface is a vacuum interface.

In some embodiments, the interface is a rigid interface.

In some embodiments, the interface is a flexible interface.

In some embodiments, the flexible interface includes a bellows.

In some embodiments, the flexible interface includes two or more bellows at an angle relative to each other.

In some embodiments, the flexible interface includes two or more bellows in line with each other.

In some embodiments, the flexible interface includes two or more bellows in parallel with each other.

In some embodiments, the flexible interface includes two or more bellows in series with each other.

In some embodiments, the specimen holder further includes one or more damping materials.

In some embodiments, the one or more damping materials include a viscoelastic material.

In some embodiments, the one or more damping materials are in parallel with each other.

In some embodiments, the one or more damping materials are in series with each other.

In some embodiments, the flexible interface includes two or more damping materials with different resonant frequencies.

In some embodiments, the specimen holder is configured to attach to the cooling device such that the cooling device is aligned axially with the section with the sample tip.

In some embodiments, the specimen holder is configured to attach to the cooling device such that the cooling device is aligned perpendicularly with the section with the sample tip.

In some embodiments, the specimen holder is configured to attach to the cooling device such that the cooling device is aligned at an angle relative to the section with the sample tip.

In some embodiments, the interior of the specimen holder is configured to be under a vacuum.

In some embodiments, the vacuum is supplied by the microscope.

In some embodiments, the specimen holder includes at least one access port.

In some embodiments, the access ports provide access for at least one of electrical wires, fiber optics, gas, heat, and mechanical motion.

In some embodiments, the specimen holder further includes a sensor.

In some embodiments, the sensor is a temperature sensor.

In some embodiments, the temperature sensor is located near the sample tip.

In some embodiments, the temperature sensor is located near or at the cold finger when the specimen holder is attached to the cooling device.

In some embodiments, the temperature sensor is configured to provide feedback for temperature control.

In some embodiments, temperature control is provided by regulating flow of a cryogenic liquid or a cryogenic gas.

In some embodiments, temperature control is provided by a heater.

In some embodiments, the specimen holder further includes a heater.

In some embodiments, the heater is located near the sample tip.

In some embodiments, the heater is located near or at the cold finger when the specimen holder is attached to the cooling device.

In some embodiments, the specimen holder is configured to maintain a temperature stability of less than about 5 mK.

In some embodiments, the specimen holder is configured to maintain a temperature stability of less than about 5 mK for at least 4 hours.

In some embodiments, the sensor includes a vibration sensor.

In some embodiments, the vibration sensor is located between the first end and a flexible interface.

In some embodiments, the vibration sensor is located between a flexible interface and the second end.

In some embodiments, the vibration sensor is located near the sample tip.

In some embodiments, the vibration sensor is configured to provide feedback for vibration control.

In some embodiments, vibration control is provided by tuning a resonant frequency of a component of a flexible interface based on a reading of the vibration sensor.

In some embodiments, vibration control is provided using an actuator to counteract vibrations based on a reading of the vibration sensor.

In some embodiments, the sample tip includes a plate and a hole.

In some embodiments, the sample tip includes a board to allow electrical contact with the sample.

In some embodiments, the sample tip includes multiple rotatable parts.

In some embodiments, one or more portions of the specimen holder are covered by one or more layers of a reflective material.

In some embodiments, the specimen holder is configured to position the sample tip in the microscope.

In some embodiments, the flexible interface allows displacement along at least one of the x-axis, y-axis, and z-axis.

In some embodiments, the flexible interface allows tilt about the longitudinal axis of the specimen holder.

In some embodiments, the flexible interface allows rotation about the longitudinal axis of the specimen holder.

In some embodiments, the section with the sample tip includes a tube.

In one aspect, a system includes the specimen holder disclosed herein; and a support fixed to the cooling device.

In some embodiments, the support rests on a vibration isolation structure.

In some embodiments, the vibration isolation structure is selected from the list consisting of optical tables, eddy-current-damped platforms, negative stiffness isolators, pneumatic isolators, and a combination thereof.

In some embodiments, the support includes one or more springs.

In some embodiments, the one or more springs have a resonant frequency less than 5 Hz.

In some embodiments, the support includes an actuator-based vibration suppressor. In some embodiments, the support is configured to be anchored to a heavy mass.

In some embodiments, the support is configured to be anchored to a microscope.

In some embodiments, the support is configured to adjust the specimen holder.

In some embodiments, the support structure is configured to displace the specimen holder along at least one of the x-axis, y-axis, and z-axis.

In some embodiments, the support structure is configured to tilt the specimen holder about the longitudinal axis of the specimen holder.

In some embodiments, the support structure is configured to rotate the specimen holder about the longitudinal axis of the specimen holder.

In some embodiments, the support structure is covered with a sound absorbing or a sound reflecting material.

In one aspect, a method includes providing the specimen holder disclosed herein; attaching a sample to the sample tip; aligning the specimen holder with an access port of the microscope; inserting the sample tip into the microscope; cooling the sample to a base temperature; and imaging the sample using the microscope.

In some embodiments, aligning includes using a motorized stage.

In some embodiments, aligning includes clamping a flexible interface.

In some embodiments, the method further includes forming a vacuum in the interior of the specimen holder.

In some embodiments, the cooling device is a flow-cryostat and cooling includes inserting a first end of a transfer line into the flow-cryostat, inserting a second end of the transfer line into a dewar, and pressurizing the dewar to flow a cryogenic liquid.

In some embodiments, the method further includes controlling flow of the cryogenic liquid based on a measured temperature.

In some embodiments, the cooling device is a closed-cycle cryostat and cooling includes turning on a compressor and refrigerating a cryogenic gas.

In some embodiments, the cooling device is a bath cryostat, and cooling includes transferring a cryogenic liquid to a dewar.

In some embodiments, the method further includes applying a stimulus to the sample.

In some embodiments, the method further includes measuring the sample using one or more sensors.

In some embodiments, the method further includes fixing the cooling device to a support.

In some embodiments, the method further includes monitoring temperature at a location of the specimen holder.

In some embodiments, the method further includes monitoring temperature near the sample tip.

In some embodiments, the method further includes monitor temperature at the cold finger.

In some embodiments, wherein monitoring temperature provides feedback for temperature control.

In some embodiments, temperature control is provided by regulating flow of a cryogenic liquid or a cryogenic gas.

In some embodiments, temperature control is provided by a heater.

In some embodiments, the method further includes heating a portion of the specimen holder.

In some embodiments, heating includes heating near the sample tip.

In some embodiments, heating includes heating the cold finger.

In some embodiments, the method further includes maintaining a temperature stability of less than 5 mK.

In some embodiments, the method further includes maintaining a temperature stability of less than about 5 mK for at least 4 hours.

In some embodiments, the method further includes monitoring vibrations at a location of the specimen holder.

In some embodiments, the method further includes monitoring vibrations at a location between the first end and a flexible interface.

In some embodiments, the method further includes monitoring vibrations at a location between a flexible interface and the second end.

In some embodiments, the method further includes monitoring vibrations near the sample tip.

In some embodiments, monitoring vibrations provides feedback for vibration control.

In some embodiments, vibration control is provided by tuning a resonant frequency of a component of a flexible interface based on a reading of a vibration sensor.

In some embodiments, vibration control is provided using an actuator to counteract vibrations based on a reading of a vibration sensor.

In some embodiments, the method further includes reducing the pressure of a cryogenic liquid or a cryogenic gas.

In some embodiments, the method further includes recycling a cryogenic liquid or a cryogenic gas.

Any aspect or embodiment disclosed herein may be combined with another aspect or embodiment disclosed herein. The combination of one or more embodiments described herein with other one or more embodiments described herein is expressly contemplated.

### BRIEF DESCRIPTION OF THE DRAWINGS

The objects and advantages will be apparent upon consideration of the following detailed description, taken in conjunction with the accompanying drawings, in which like reference characters refer to like parts throughout, and in which:

FIGS. 1A-1B shows schematics of a specimen holder, according to certain embodiments.

FIG. 2A shows a view of the inside of a specimen holder with a flexible thermal connection and a high thermal conductivity cooling rod, according to certain embodiments.

FIG. 2B shows a low thermal conductivity retaining ring, according to certain embodiments.

FIG. 2C shows a view of the inside of a specimen holder with a high thermal conductivity braid, according to certain embodiments.

FIG. 2D shows a schematic of specimen holder with a collar, according to certain embodiments.

FIG. 2E shows an exploded view of a specimen holder with a collar, according to certain embodiments.

FIG. 3A shows a schematic of single-bellows design, according to certain embodiments.

FIG. 3B shows a schematic of single-bellows design, according to certain embodiments.

FIG. 3C shows a schematic of single-bellows design, according to certain embodiments.

FIG. 3D shows a schematic of single-bellows design, according to certain embodiments.

FIG. 4A shows a schematic of double-bellows design, according to certain embodiments.

FIG. 4B shows a schematic of double-bellows design, according to certain embodiments.

FIG. 5A shows a schematic representation of a damping material, according to certain embodiments.

FIG. 5B shows schematic of a flexible interface with a bellows and with dampers arranged in parallel, according to certain embodiments.

FIG. 5C shows schematic of a flexible interface with a bellows and with dampers arranged in series and in parallel, according to certain embodiments.

FIG. 5D shows schematic of a flexible interface with two bellows arranged in series and with dampers arranged in parallel, according to certain embodiments.

FIGS. 5E-5F show a photograph of a flexible interface with a bellows and dampers, according to certain embodiments.

FIG. 6A shows a schematic of support of a specimen holder, according to certain embodiments.

FIG. 6B shows a photograph of a support of a specimen holder, according to certain embodiments.

FIG. 6C shows a photograph of a support of a specimen holder, according to certain embodiments.

FIG. 7 shows a schematic specimen holder with a cooling device is aligned perpendicularly with the tube section, according to certain embodiments.

FIG. 8A shows a set-up of a specimen holder used for vibration monitoring experiments, according to certain embodiments.

FIG. 8B shows amplitude of vibrations measured during vibration monitoring experiments, according to certain embodiments.

FIG. 9A shows the distribution of temperature of a specimen holder measured at a base temperature of 11K, according to certain embodiments.

FIG. 9B shows the temperature over time of a specimen holder measured at a base temperature of 11K, according to certain embodiments.

FIG. 9C shows the distribution of temperature of a specimen holder measured at an intermediate temperature of 110K, according to certain embodiments.

FIG. 9D shows the temperature over time of a specimen holder measured at an intermediate temperature of 110K, according to certain embodiments.

### DETAILED DESCRIPTION

In one aspect, a specimen holder includes a first end configured to attach to a cooling device and a second end configured to be inserted into a microscope; a section with a sample tip at the second end; an interface between the first end configured to attach to the cooling device and the section with the sample tip; and an internal thermal connection section configured to be in thermal contact with a cold finger of the cooling device when the specimen holder is attached to the cooling device and extending through the section with the sample tip to the sample tip.

When imaging materials at low temperatures, using, e.g., transmission electron microscopes, it can be challenging to maintain temperature stability over long periods of time. Additionally, when imaging materials at high resolution using, e.g., transmission electron microscopes, vibrations and instability introduced by cooling limit the resolution. Reducing vibrations is important when atomic-scale resolution is desired. Another challenge in low-temperature electron microscopy is the limited physical space that makes the introduction of cryogens and other stimuli challenging, especially when a cryogen is unwieldy, for example, as in the case of helium. Specimen holder designs, such as side-entry holders used in transmission electron microscopy (TEM), suffer from many shortcomings. Due to these shortcomings, the use of helium, and even nitrogen, is ineffectual for stable high-resolution microscopy management designs.

For example, if a cooling liquid is introduced to specimen using a dewar rigidly attached to the holder, there are several drawbacks. Such dewars are generally small to reduce the mass of the dewar, resulting in frequent refilling and a constantly changing liquid level, which affects the temperature drift and causes violent cryogen bubbling and evaporation. This results in limited temperature stability and vibrations that limit resolution of the image. If a specimen holder instead holds a cooling liquid in a small dewar and then internally circulates the liquid to a sample on the tip, large vibrations are introduced by the flowing and bubbling helium within the electron microscope holder section. If a larger dewar is used, re-filling is less frequent, but the dewar is connected open to ambient air, resulting in ice formation and gas conductions. If an open dewar is used, there is a limit on temperature because an open dewar can be used for liquid nitrogen, but not liquid helium.

The specimen holder disclosed herein combines a cooling device, for example, a helium-compatible cryostat interface, with mechanical coupling and thermal management designs to address these challenges. In some embodiments, the specimen holder disclosed herein also provides vibration isolation and damping. It was surprisingly found that the specimen holder disclosed herein can have one or more the following advantages for high-resolution electron microscopy at low temperatures.

First, in some embodiments, the specimen holder can cool below liquid nitrogen boiling temperatures and is compatible with liquid helium. This allows imaging at temperatures as low as about 77K using liquid nitrogen or about 4K using helium. In some embodiments, the temperature can be lowered further, e.g., to about 1.8 K, by using helium with the pressure lowered, e.g., using a pump. Compatibility with a variety of cooling liquids or cryogens at a variety of pressures provides additional flexibility. For example, lowering pressure can reduce the boiling point of a cryogenic liquid. In some embodiments, the pressure can be increased or decreased relative to atmosphere to reduce evaporation (e.g., for a bath cryostat) or achieve low temperatures (e.g., for a bath cryostat or flow cryostat). For example, cooling with helium makes it possible to image materials that operate at very low temperatures such as those used in quantum computing or instruments in space. Additionally, imaging near helium boiling temperature improves the coherence of spectroscopic signals, signal detector efficiency, and the resistance of materials to irradiation.

Second, in some embodiments, e.g., in contexts where reducing vibrations is important, the specimen holder can include a flexible interface that decouple vibrations introduced by the cooling device (e.g., due to boiling of the cooling liquid) from the sample. Reducing vibration is important in high-resolution applications such as electron microscopy where atomic-scale resolution is desired. Vibrations and instability introduced by the cooling liquid limit the resolution. The specimen holder reduces vibrations via a flexible interface that decouples the sample from vibrations of the cooling device.

Third, in some embodiments, the specimen holder can include a flexible interface that is mechanically compliant and allows the sample to be moved independently of the cooling device. This allows positioning of the sample within an electron microscope and allows the user to re-position the sample within the microscope without having to remove the sample from the microscope. Removing and re-inserting the sample to re-position adds to imaging time because a vacuum would need to be regenerated in some electron microscopy applications. For example, for electron microscopy, the sample can be positioned on length scales on the order of a few millimeters in the plane and about 60° total for tilt, depending on tip design. Mechanical compliance of the specimen holder enables the alignment of the sample to the electron beam so that crystalline materials can be viewed from a favorable orientation. Positioning also enables imaging different parts of the sample at the microscale, to better understand the sample properties at those scales.

Fourth, in some embodiments, the specimen holder can operate under high vacuum. Vacuum allows the specimen holder to avoid formation of ice, which can occur when a cooling apparatus contacts atmosphere. Vacuum also allows the specimen holder to avoid gas conduction and convection, either of which can limit the cooling performance and temperature stability.

Fifth, in some embodiments, the specimen holder contains viewports and access ports to let in various external stimuli including motion, electrical stimulation, heat, fiber optics, light, gases and more.

Sixth, in some embodiments, the specimen holder can be continuously operatable for many days and does not require frequent refilling of the cooling liquid, which disturbs the experiment. Interacting with the device, including to refill the cooling liquid, introduces vibrations and requires time for settling after refilling. For example, if a smaller dewar or open dewar is used, the dewar requires a top-off every hour or so, each time causing temperature and sample position to drift. In contrast, the specimen holder described herein is operable for longer time periods. For example, the specimen holder is continuously operatable for at least three hours, depending on the size of an external dewar. In some embodiments, the specimen holder is continuously operable for 100 hours using a 100 L external dewar or for longer periods using a dewar with a volume of 250 or more liters. In some embodiments, the specimen holder is continuously operatable for long periods because it provides one or more of the following properties: temperature stability, low sample drift, and vibrational stability. For example, it was surprisingly found that the specimen holder can provide temperature stability of less than about 5 mK or less than about 2 mK over many hours, e.g., at least 4 hours. For example, it was surprisingly found that the specimen holder can provide reduced sample drift, for example, because temperature stability reduces thermal expansion or contraction of parts due to thermal fluctuations.

It was surprisingly found that the specimen holder disclosed herein can achieve these advantages using a cooling device such as a cryostat to cool a sample and coupling the cooling device to the sample with an interface and an internal thermal connection. In some embodiments, e.g., in contexts where reducing vibrations is important, the interface can be flexible. In some embodiments, e.g., in contexts where it is not necessary to reduce vibrations, the interface can be rigid. In some embodiments, the internal thermal connection configured to be in contact with a cold portion (e.g., a cold finger) of the cryostat. In some embodiments, e.g., in contexts where reducing vibrations is important, the internal thermal connection can include a flexible portion. A flexible internal thermal connection can be combined with either a flexible interface or a rigid interface. In some embodiments, e.g., in contexts where it is not necessary to reduce vibrations, the internal thermal connection can be rigid. A rigid internal thermal connection can be combined with either a flexible interface or a rigid interface.

Non limiting examples of cryostats include flow cryostats, closed cycle cryostats, and bath cryostats (e.g., with a large dewar). A cryostat uses a cryogen such as a cooling liquid (e.g., liquid nitrogen or helium) or cooling gas and creates a cold tip or cold finger to which a sample or device can be thermally coupled. A cryostat provides the advantage of ease of handling the cryogen since the cryostat can either flow the cryogen from a large reservoir through a transfer tube (for, example in a flow cryostat) or utilize mechanical or pneumatic refrigeration methods to cool the cold finger (for example, in a closed-cycle cryostat). However, mounting a sample directly on the cold finger would not allow atomic-resolution due to remnant vibrations from the flow and boiling of the cryogen through a transfer tube and cold finger or to mechanical and pressure oscillations. Therefore, the specimen holder disclosed herein can reduce the vibrations emanating from the cryostat near the cold finger (e.g., through the flow of cryogen and gas or in the case of closed-cycle cryostat the mechanical vibration). In some embodiments, the specimen holder disclosed herein also decouples the vibrations emanating from the cryostat near the cold finger.

Additionally, the specimen holder combines this technology with the side-entry holders so that a sample in modern instruments such as electron microscopes may be cooled and maintained in a vibration-free environment. For example, the specimen holder can be introduced from any available side ports in a microscope. In these examples, the specimen holder can use its own pump to get vacuum before opening a valve and inserting the specimen holder into the microscope. Any suitable loadlock can be used, e.g., using a gate or butterfly valve. The specimen holder can be configured so that attachment of the specimen holder to the cryostat does not hinder the ability to move the specimen holder in 5 directions (x, y, z, tilt around x, tilt around y), which allows the sample to be aligned with the electron microscope. In some embodiments, a compliant flexible interface (e.g., compliant bellows) can allow motion of a stage in x, y, and x while under vacuum. In some embodiments, use of a support structure with adjustable degrees of freedom can allow motion in x, y, and z while under vacuum with either a flexible or a rigid interface.

In some embodiments, the specimen holder disclosed herein can also provide improved temperature control of the specimen holder and sample. In some embodiments, maintaining a stable temperature during operation of the microscope is important to minimize the effects of drift. Drift can be caused, for example, by contractions or expansion of the sample or specimen holder or by movement of the sample during imaging. When using an open dewar to cool a sample, temperature control is limited by the small, exposed dewar, which causes temperature to vary rapidly, and counteracting these fluctuations is difficult. In some embodiments, temperature fluctuations less than about 1 K or less than about 5 mK over extended periods of time are desirable. In contrast, using an open dewar to cool a sample can result in fluctuations larger than about 5 mK over periods of only a few seconds or minutes. For example, after the cryogen evaporates from an open dewar over timescales of minutes, fluctuations can be much larger, and the assembly can warm up rapidly towards ambient temperature (rising by many degrees). In some embodiments, when using the specimen holder disclosed herein, it was surprisingly found that the temperature is stable with variations of less than about 5 mK over extended periods of time, for example hours. Maintaining a stable temperature can result in less drift, longer experiments, and more accurate measurements. For example, many imaging measurement techniques, such as chemical mapping and inelastic measurements, have an inherently weak signal and thus require collection for longer periods, up to hours.

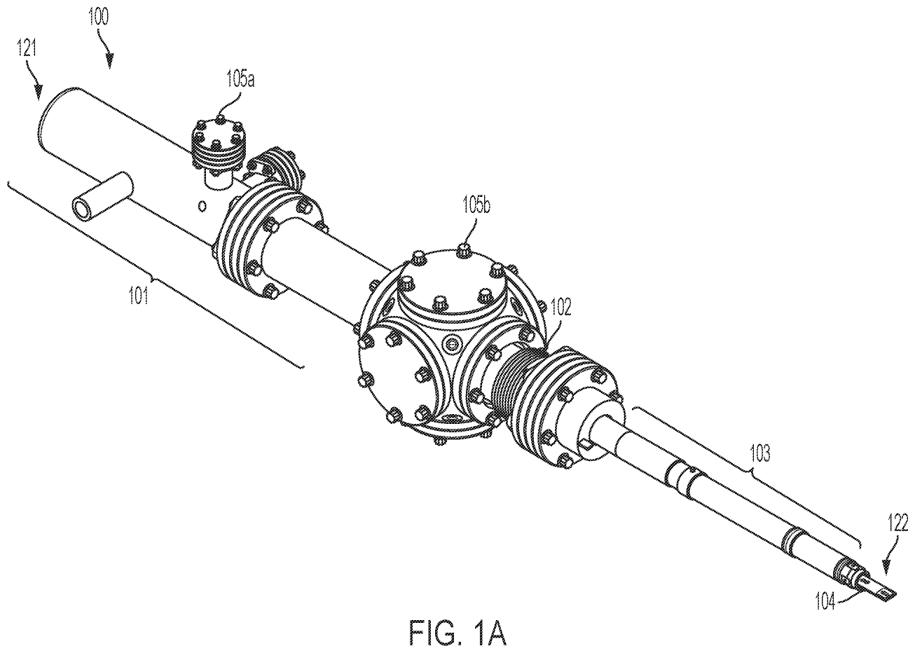

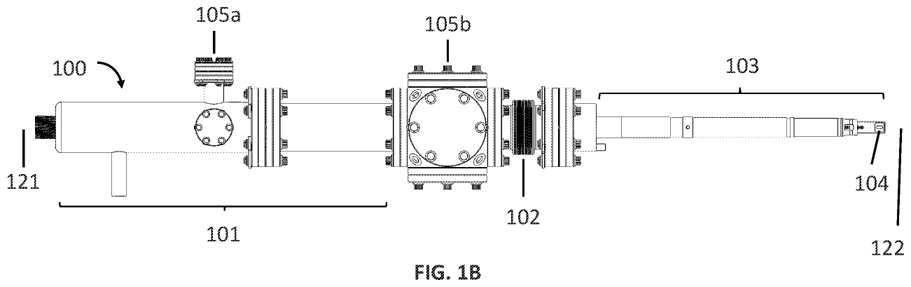

FIGS. 1A-1B show a schematic of an illustrative specimen holder 100 for a microscope 122. In the examples shown in FIGS. 1A-1B, the specimen holder includes a flexible interface 102. The specimen holder 100 includes or is configured to attach to a cooling device 101 that accepts a cryogenic liquid from a reservoir 121 at a first end and is configured to interface with a microscope 122 at a second end. The specimen holder includes a section, e.g., a tube section, 103 with a sample tip 104 at the second end that can be inserted into the microscope 122. In this example, the cooling device 101 is connected to the tube section 103 via a flexible, low vibration interface 102 that decouples vibrations of the cooling device from the sample tip 104 of the specimen holder. The interior of the tube section 103 can contain components such as electrical wires, motion rod, sealed gas tubes that are routed towards the tip section. In some embodiments, the specimen holder includes access ports 105a, 105b for electrical wires and fiber optic cables. The interior of the specimen holder can include a component that attaches to the cold finger at one end and the tip at the other end to remove heat from a sample.

Non limiting examples of microscopes include transmission electron microscopes, scanning electron microscopes, focused ion beam microscopes, atomic-force microscopes, and optical microscopes. For example, the specimen holder is particularly useful in complex microscopes that combine many functionalities and suffer from limited space as a result. In some embodiments, the specimen holder is adapted for side-entry of a microscope, for example an electron microscope.

The specimen holder is configured at one end to attach to a cooling device 101, for example, a cryostat that accepts a cryogenic liquid or cryogen from a reservoir 121. In some embodiments, the specimen holder is attached to or configured to attach to the cooling device. In some embodiments, the specimen holder includes the cooling device.

In some embodiments section with the sample tip (e.g., tube section) 103 can hold a vacuum after insertion into the microscope, and various elements can be routed through this evacuated tube. In some embodiments, the vacuum is generated using the vacuum of the electron microscope. In other embodiments, a separate vacuum is used and connected via one of the access ports. When using a separate vacuum, the vacuum pump is preferably further away from the microscope and specimen holder to avoid transmission of vibrations to the specimen holder. In some embodiments, a separate vacuum is used in addition to that of the microscope. Use of both a separate vacuum and the microscope vacuum accelerates pump down times.

In some embodiments, the specimen holder includes an interface between the end of the specimen holder configured to attach to the cooling device and the section 103 with the sample tip. In some embodiments, a flexible interface 102 allows decoupling of vibrations caused by the cryogen and cooling device 101 from the section 103 and from the tip 104 of the specimen holder, where the sample is placed. The flexible interface allows for relative motion between the cooling device and the section with the sample tip or between any parts of the system. This relative motion allows both decoupling of vibrations and positioning of the sample in the microscope. The flexible interface also acts as a low vibration interface. In some embodiments, the flexible interface allows for vibration isolation by stopping mechanical and acoustic vibrations whose frequency is mismatched to a resonance frequency of the flexible interface. In some embodiments, the flexible interface includes a bellows. In some embodiments, the bellows is supported by damping material connecting the two ends of the flexible interface. The damping material helps reduce the transfer of vibrations. In some embodiments, one or more damping materials can be arranged in different sequences or arrangements (e.g., in parallel or in series) and have different resonant frequencies. In the example shown in FIGS. 1A-1B, the flexible interface is a bellows.

In some embodiments, the cooling device is mechanically decoupled from the microscope and specimen holder via a flexible interface. In some embodiments, the cooling device rests on its own mechanical support. In interior sections of the specimen holder, ribbons, braids, springs, or other flexible connections can also limit vibrations. In some embodiments, the cooling device is connected to the specimen holder via flexible vacuum bellows. This allows some mechanical compliance (movement of the holder to navigate the sample space), which is an important requirement for the operation of microscopy, as well as vibration isolation. In some embodiments, the flexible interface, based on the flexible bellows and the flexible interior connections, also decouples vibrations and limits their transfer to the sample being imaged.

In some embodiments, additional strategies can be used to suppress vibration. For example, the cooling device support may rest on passive- or active-vibration isolation structures. For example, supports can reduce vibrations whether the specimen holder includes a rigid interface or a flexible interface. Non-limiting examples of support isolation structure include as optical tables, eddy-current-damped platforms, negative stiffness isolators, pneumatic isolators, actuator-based vibration suppressors (active vibration suppression), suspension, anchoring to a heavy mass, or a combination thereof. In another example, the cryostat and transfer line may be wrapped and squeezed in damping material to damp vibrations before they reach the interface. For example, the cooling device can be suspended using springs whose resonant frequency is carefully designed by tuning the mass and spring constant of the assembly, rather than resting on a support. For example, a sub 5-Hz resonant frequency is achievable, which strongly isolates any vibrations above 5 Hz. Remnant vibration can be further suppressed by combining other vibration isolation and damping methods such as eddy-current damping.

In some embodiments, a support structure can be anchored to a large mass to suppress vibrations. In some embodiments, a large mass is at least 100 kg or at least 1000 kg. In some embodiments, the mass is on the order of the mass of a microscope. Non-limiting examples of large masses include concrete, a lead-filled table, the microscope itself, and combinations thereof. In some embodiments, anchoring a support structure to the microscope can be beneficial because a microscope is often the largest mass in the room and because a microscope is often mounted on a vibration isolation platform. In some embodiments, a support structure can be mounted on the isolation platform of the microscope. In some embodiments, an isolation platform uses passive, active or combination of passive and active isolation strategies. In some embodiments, a support structure can be suspended. For example, a support structure can be suspended by springs from an anchor. For example, a support structure can be suspended from a microscope, either with or without springs.

In some embodiments, a support structure has adjustable degrees of freedom for alignment of the specimen holder with a microscope. For example, a support structure can allow alignment of the specimen holder with the microscope whether the specimen holder includes a rigid interface or a flexible interface. In some embodiments, the support structure allows displacement of the specimen holder along at least one of the x-axis, y-axis, and z-axis. In some embodiments, the support structure allows tilt of the specimen holder, e.g., tilt about the longitudinal axis of the specimen holder. In some embodiments, the support structure allows rotation of the specimen holder, e.g., rotation about the longitudinal axis of the specimen holder. For example, a support structure can be adjusted in one or more of the following ways: (1) planarity can be adjusted using adjustment screws or feet, (2) x, y, and z displacement can be adjusted with actuators or sliders to align the specimen holder with an entrance port, (3) pitch and yaw can also be added, e.g., using rotational micrometers, actuators, or sliders. In some embodiments, movement of a support structure can be motorized or driven by hydraulics for ease of movement. In some embodiments, the support structure includes brackets that hold the specimen holder. In some embodiments, a bracket can keep the specimen holder secured in the support structure while allowing rotation along the longitudinal axis of the specimen holder. Such a bracket can be useful, for example, when loading the sample tip into a microscope, for example if the port of the microscope is opened via rotating the specimen holder to open a vacuum valve. In some embodiments, slight misalignment can be absorbed by a flexible interface (e.g., bellows) of the specimen holder or by fine adjustment to the X,Y,Z, and planarity by the support structure.

In some embodiments, the support structure can provide additional vibration isolation to the system. For example, the support structure can be covered with panels containing foam, sound deadening material, anechoic panels, sound reflecting material, sound absorbing material, a baffle to create circuitous air paths, and/or various layers or a combination thereof. Covering the support structure with such material or panels can limit the effect on the specimen holder of pressure waves and sound in the room. In some embodiments, these panels can make a hermetic seal between the support structure and the microscope. In some embodiments, the support structure can include temperature control, for example, a radiative heater or quiet fans, to maintain the outside temperature of the specimen holder. In some embodiments, heaters and sensors can also be attached to the outside of the specimen holder to help control its temperature and reduce the effect of fluctuations in the room. In these embodiments, connections to the specimen holder can be routed through hermetic feedthroughs in the panels of the support structure.

In some embodiments, the ends of the bellows in a flexible interface are connected and supported via a flexible, damping material. In some embodiments, a damping material is viscoelastic. For example, a viscoelastic damping material can maintain compliance and vibration damping. Non-limiting examples of damping materials include Viton, thermoplastics, foams, urethane, sorbothane, rubber, and a combination thereof. Alternatively, a spring can provide damping. In some embodiments, eddy current damping is provided using a permanent magnet and a conducting plate. In some embodiments, the damping material further enhances the performance of the flexible interface by suppressing high-frequency vibrations that may emanate, for example, from the cryostat operation.

In some embodiments, a flexible interface can include any combination of one or more bellows with damping materials in various configurations. For example, two or more bellows can be arranged axially, vertically, perpendicularly, or at an intermediate angle to one another. In some embodiments, bellows can be arranged in series. In some embodiments, bellows can be arranged in parallel to each other. In some embodiments, a bellows can be arranged in parallel with one more damping materials. For example, a bellows can be arranged with one or more damping materials connecting the ends of the bellows. In some embodiments, damping materials connecting the ends of bellows can be arranged in series or in parallel. In some embodiments, a flexible interface can include two or more damping materials with different properties, for example with different resonant frequencies. For example, the hardness of a damping material can be varied by vacuum contraction of a bellows. For example, by including damping materials with a range of different resonant frequencies, a flexible interface can provide vibration isolation for a range of vibration frequencies.

The tip 104 of the specimen holder is configured to interface with an electron microscope 122. The sample can be placed at the tip 104 of the specimen holder, which is configured to be inserted into a microscope 122. In some embodiments, the tip is inserted into an access port of the microscope such that the tip is located precisely in the path of the microscope imaging particles (e.g., light, electrons, ions). In some embodiments, the tip is a simple plate upon which a specimen is placed, for example a simple plate with a hole. In other embodiments, the tip is more complex.

In some embodiments, the tip includes electronic boards for accepting electrical wires or electrical connection to allow electrical contact to the sample. In some embodiments, electrical contacts can be used to electrically excite the sample, measure its resistance, or bias/gate the sample to measure or activate its electronic properties. For example, the resistance of superconductors or semiconductors can be measured at low temperatures, and this behavior can be correlated to microscopic images. In another example, wires are used to measure the local temperature using a sensor or to excite a small heater near the sample to change the local temperature of the sample, for example, to change the temperature relative to the base temperature of the cryostat. In some embodiments, electrical contacts actuate an electromechanical actuator, for example, a transducer, which interacts with the sample by stressing or squeezing the sample to measure or induce the mechanical properties of the material under investigation. In some embodiments, a transducer can also trigger mechanical tilt and rotation of the sample tip.

In some embodiments, the tip can include multiple hinged parts to allow for tilt around the axis perpendicular to the holder axis using actuation from a rod. For example, this could allow tilt or rotation of the sample relative to the imaging axis. In some embodiments, the tilt is actuated using mechanical or electromechanical means.

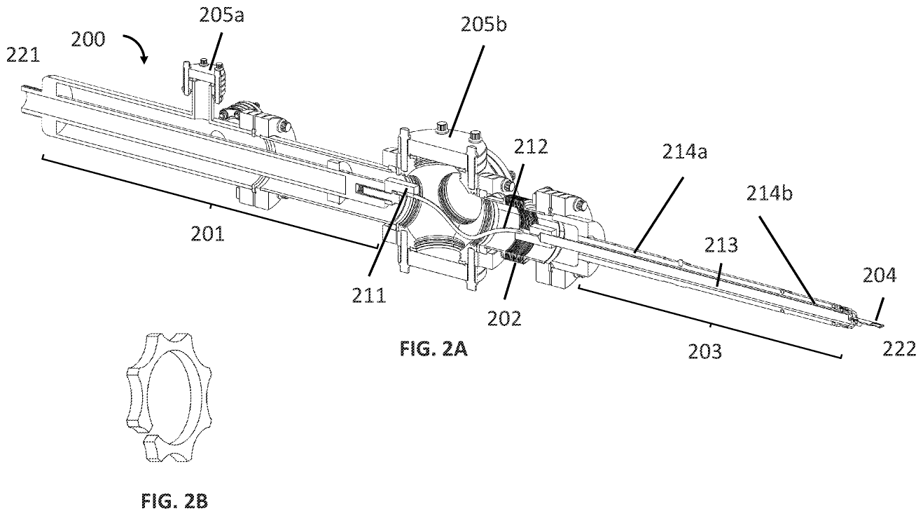

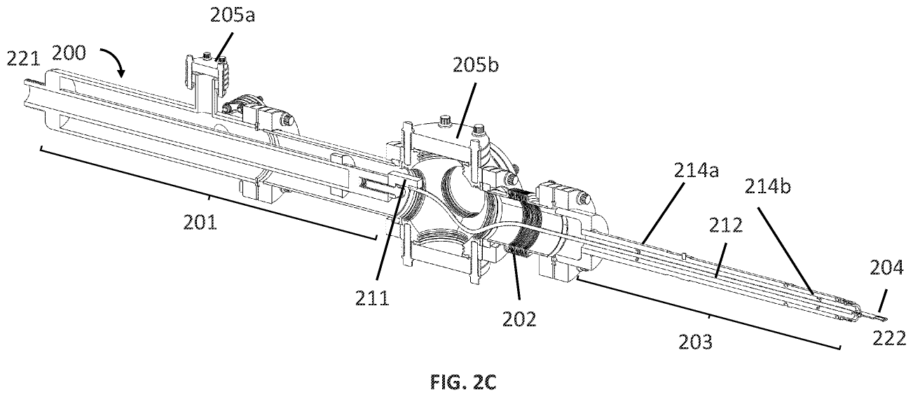

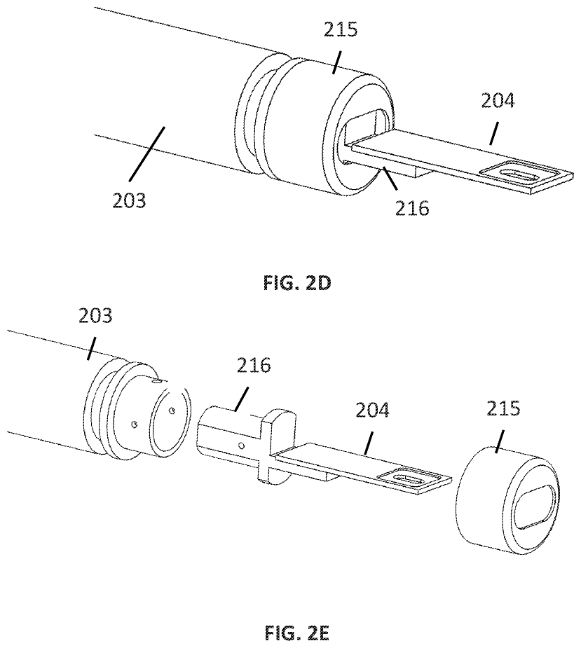

FIGS. 2A-2C show internal components of an illustrative specimen holder 200. In the examples shown in FIGS. 2A-2C, the specimen holder includes a flexible interface and an internal thermal connection that includes a flexible portion. As shown in FIGS. 2A and 2C, the specimen holder includes a cooling device 201 that accepts a cryogenic liquid from a reservoir 221 and is configured to interface with a microscope 222. In this example, the cooling device is connected to a section 203 (e.g., a tube section) via a flexible, low vibration interface 202 that decouples vibrations of the cooling device from the tip 204 of the specimen holder. The interior of the section 203 can contain components such as electrical wires, motion rod, sealed gas tubes that are routed towards the tip section. In some embodiments, the specimen holder includes access ports 205a, 205b for electrical wires and fiber optic cables.

As shown in FIGS. 2A and 2C, the cooling device 201 includes a cold finger 211 that generates a localized cold surface within the cooling device. In some embodiments, the cold finger includes a high thermal conductivity material. In some embodiments, the cold finger is made from copper, although other materials with similar thermal, mechanical, and machinability properties can be used.

In some embodiments, the cooling device is a cryostat. In some embodiments, the cooling device includes a flow cryostat that accepts a cryogen from a reservoir, routs the cryogen through a heat exchanger, and thereby extracts heat from the cold finger. In some embodiments, the cooling device includes a closed-cycle cryostat which uses a mechanical or pneumatic refrigerator of gas vapor to extract heat from the cold finger. In some embodiments, the cooling device includes a bath cryostat or dewar design for providing a cold finger. The specimen holder disclosed herein offers improvements for a bath cryostat. For example, the bath cryostat can be independently supported and be as large as needed (for example, so that refilling is not required within a day), the thermal connection between the cryostat and cold finger is under high vacuum, the flexible interface in the outer and inner section reduce mechanical coupling and vibrations (for example, by using bellows in the outer section and a flexible braid in the inner section), and the bath cryostat can be pressurized (for example, to reduce evaporation, bubbling, or vibration). In some embodiments, if external heaters are used for the cryostat, these heaters are electrically disconnected from the specimen holder or use an external DC power supply. This can avoid triggering touch alarms in microscopes and further reduce vibrations.

When the specimen holder 200 is attached to the cooling device 201, an internal thermal connection section within the section with the sample tip 203 connects the cold finger 211 to the tip 204 of the specimen holder to extract heat from and cool the sample. The internal thermal connection section is in thermal contact with both the cold finger and the tip. In some embodiments, e.g., in contexts where reducing vibrations is important, the internal thermal connection can include a flexible portion. In embodiments, where the internal thermal connection includes a flexible portion, the internal thermal connection can reduce mechanical coupling between the cold finger and the tip. For example, in some embodiments, the internal thermal connection section can include a flexible portion to reduce mechanical coupling and vibrations. In some embodiments, e.g., in contexts where it is not necessary to reduce vibrations, the internal thermal connection can be rigid. In some embodiments, the section 203 is under high vacuum to minimize effects of gas convection and conduction and accumulation of frost.

In some embodiments, the internal thermal connection section is made of a thermally conductive material. Non-limiting examples of thermally conductive materials include copper, silver, aluminum, or sapphire. In some embodiments, the internal thermal connection section is made of a high-purity thermally conductive material, for example, 99.99% or above purity copper, silver, aluminum, quartz, or sapphire. In some embodiments, these materials are annealed to further improve their thermal properties or plated with an inert metal (e.g., gold or other noble metals) to protect surfaces from degradation. FIGS. 2A and 2C show two exemplary configurations of an internal thermal connection section that can extract heat from the sample tip while also reducing vibrations transmitted to the sample.

FIG. 2A shows an example of an internal thermal connection section that includes a combination of a flexible portion 212 and a rigid portion 213, both of which are made of high conductivity materials. The flexible portion 212 acts as a flexible connection between the cold finger 211 and the rigid portion 213 that is disposed within the section with the sample tip 203. In this example, the flexible portion 212 connects to the rigid portion at the flexible interface 202. The rigid portion 213 is connected to the tip 204 and extracts heat from the sample at the tip. The flexible portion allows for thermal connection between the cold finger and rigid portion while suppressing mechanical coupling between these components. In some embodiments, thermal connections (e.g., between the cold finger and flexible portion or between the flexible portion and rigid portion or between the rigid portion and tip) can be enhanced by squeezing a soft, thermally conductive material (e.g., Indium) or cryogenic grease at the connection or by gold plating parts. In some embodiments, other known metal joining techniques such as electron beam welding can be used to form thermal connections.

Non-limiting examples of configurations of the flexible portion include braids, sleeves, springs, wire bundles, straps, and a combination thereof. In some embodiments, the flexible portion includes a metal. Non-limiting examples of metals for the flexible portion include silver, copper, aluminum, and a combination thereof. In one example, the flexible portion includes thin flexible wires (e.g., 25 μm or thinner), connecting the cold finger and the rigid portion. In some embodiments, the flexible portion is annealed to further improve its thermal properties or plated with an inert metal (e.g., gold or other noble metals) to protect its surface from degradation. In some embodiments, the rigid portion includes a rod. Non-limiting examples of materials for the rigid portion include silver, copper, aluminum, quartz, sapphire, and a combination thereof.

In some embodiments, the rigid portion is supported along the length of the section with the sample tip 203 by low thermal conductivity retaining rings or pins 214a, 214b, or other components that limit flow of heat from the section 203. In some embodiments, retaining rings can be used to support a rigid internal thermal connection. The retaining rings or pins provide support to the rod while also limiting transfer of heat and vibrations from the section. In some embodiments, for example, when the specimen holder is arranged horizontally, the rigid portion or rigid internal thermal connection is supported by at least two rings or pins, for example, to support the internal connection against gravity and preclude the internal connection from touching the outer jacket. In these embodiments, one ring or pin is placed at the entrance of the section (for example, near the flexible interface) and a second ring or pin is placed at a location between the midpoint of the section and the end of the section. In some embodiments, for example, when the specimen holder is arranged vertically, a single ring or pin is used.

FIG. 2B shows an illustrative retaining ring. In some embodiments, the retaining ring is a simple ring made of low-thermal conductivity material. In one embodiment, shown in FIG. 2B, the geometry of the ring is such that its outer diameter has few contact points with the inner surface of the section, limiting thermal conduction. For example, this contact can be reduced by shaving out sections from the outer circumference of the retaining ring. In some embodiments, the thickness (difference between the inner and outer diameter) of the ring is minimized to reduce the thermal conduction. Various polygonal shapes can be used for the retaining ring. For example, a retaining ring can have a triangular shape with a hole in the middle. In this example, only three points of the ring contact with the section. In some embodiments, the surface of the retaining ring is roughened at the microscale to obtain a rough texture that makes poor contact with the outer section. For example, a retaining ring can be roughened by sandblasting, using rough grades of abrasive polishing tools, or skipping polishing steps.

Various alternative retaining rings provide support to the rigid portion or rigid internal thermal connection while limiting transfer of heat and vibrations from the section. For example, the ring can be a long cylinder with a central hole. In this example, the outer diameter is such that it makes contact with the rigid portion of internal thermal connection on one end and makes contact with the section on the other end, essentially maximizing the length. In this example, thermal conductance decreases with length of the cylinder. In another example, a concentric inner tube is attached with one connection to the outer section (e.g., an outer tube). This tube is made of stainless steel or another low thermal conductivity material. In this example, the space between the inner tube and the outer tube section is under high vacuum. In this example, the internal thermal connection would then be inserted within the inner tube. This example uses the low thermal conductivity of the inner tube material (for example, stainless steel), vacuum thermal isolation, and increased thermal path to the outer tube section, resulting in very poor thermal connection between the internal thermal connection and other outer tube section. In another example, a concentric tube is broken up into segments. In this example, one or more combinations of concentric tubes can be included to increase the overall thermal path.

Non-limiting examples of low thermal conductivity materials for a pin or retaining ring include polymers, ceramics, fiberglass, thermoplastics, stainless steel, or glass. Non-limiting examples of ceramics include machinable ceramics (e.g., Macor). Non-limiting examples of thermoplastics include polyimide (e.g., vespel), PTFE, and polyesters (e.g., mylar). Non-limiting examples of glasses include Pyrex.

In other embodiments, the internal thermal connection (including the flexible portion and/or the rigid portion or a rigid thermal internal connection) is supported by layers of netting, thermal insulation, or superinsulation. In some embodiments, the netting is Mylar, polyester, nylon, silk, fiberglass, superinsulation, or a combination thereof. In some embodiments, supports such as pins, rings, and netting can reduce sag in the flexible portion. In some embodiments, the flexible portion and/or the rigid portion can also be wrapped in reflective material to reduce the effect of radiation, e.g., from warm surfaces. Non-limiting examples of reflective materials include aluminized films, aluminized mylar, aluminized Kapton, aluminized fiberglass mesh, aluminized fiberglass net, or a combination thereof. For example, cold portions of the specimen holder can be layered using a metallized insulator. For example, a radiation shield can also be a cold surface (e.g., a cooled surface) surrounding the cold portion.

In some embodiments, the internal thermal connection (including the flexible portion and/or the rigid portion or a rigid thermal internal connection) is supported by netting of low thermal conductivity material. As a non-limiting example, the netting can be layered multiple times to provide a serpentine path with a few contact points, resulting in low thermal conductance. In some embodiments, the netting is a superinsulation assembly comprising shiny or reflective radiation shield layers separated by netting or fabric of low thermal conductance material. In this way, the netting makes contact to the outer section in a few points while still maintaining an extremely low effective thermal conductance.

FIG. 2C shows an example of an internal thermal connection section that includes a flexible section 212 that connects the cold finger 211 to the tip 204 and extracts heat from the sample at the tip. In this example, the flexible portion 212 extends from the cold finger 211 and along the length of the section 203 to the tip 204, without a rigid portion. In some embodiments, thermal connections (e.g., between the cold finger and flexible portion or between the flexible portion and tip) can be enhanced by squeezing a soft, thermally conductive material (e.g., Indium) or cryogenic grease at the connection or by gold plating parts. In some embodiments, other known metal joining techniques such as electron beam welding can be used to form thermal connections.

Non-limiting examples of configurations of the flexible portion include braids, sleeves, springs, wire bundles, straps, and a combination thereof. Non-limiting examples of materials for the flexible portion include silver, copper, aluminum, and a combination thereof. In some embodiments, the flexible portion is annealed to further improve its thermal properties or plated with an inert metal (e.g., gold or other noble metals) to protect its surface from degradation.

One benefit of a flexible portion over a rigid portion is that a flexible portion can absorb length changes from thermal expansion or contraction, except at the tip, resulting in improved mechanical stability. In some embodiments, the flexible portion includes a loose braid that extends along the length of the section with the sample tip. In some embodiments, the internal thermal connection section is entirely or partially a bundle of ultra-thin wires made of high-thermal conductivity material such as copper or aluminum, which has the advantage of reducing the effect of thermal contraction of vibration transmission. In one example, the flexible portion includes thin flexible wires (e.g., 25 μm or thinner). In some embodiments, the flexible portion is supported by low thermal conductivity retaining rings or pins, such as those described above in relation to the rigid portion. In other embodiments, the flexible portion is supported by layers of netting, thermal insulation, or superinsulation. In some embodiments, the netting is Mylar, polyester, nylon, silk, fiberglass, superinsulation, or a combination thereof. In some embodiments, supports such as pins, rings, and netting can reduce sag in the flexible portion. In some embodiments, the flexible portion can also be wrapped in reflective material to reduce the effect of radiation.

In some embodiments, the flexible portion is supported by netting of low thermal conductivity material. As a non-limiting example, the netting can be layered multiple times to provide a serpentine path with a few contact points, resulting in low thermal conductance. In some embodiments, the netting is a superinsulation assembly comprising shiny or reflective radiation shield layers separated by netting or fabric of low thermal conductance material. In this way, the netting makes contact to the outer section in a few points while still maintaining an extremely low effective thermal conductance.

In some embodiments, shown in FIGS. 2D-2E, the internal thermal connection section (including the flexible portion or rigid portion or a rigid internal thermal connection) can be supported by a collar 215 at the end of the section 203 with the sample tip 204. A collar can be used in addition to or instead of retaining rings or pins to support the internal thermal connection section. In some embodiments, a collar thermally isolates the outer body of the specimen holder from the internal thermal connection section and from the sample tip. In some embodiments, a collar connects the internal thermal connection section rigidly at the tip to avoid movement of the sample. For example, a collar can allow movement of portions of the internal thermal connection section (e.g., movement of the flexible portion) while holding the tip rigidly in place at the end. One benefit of a collar at the end is that it helps constrain the motion of the tip as it contracts, leading to lower drift. Another benefit of a collar is that by mounting the tip rigidly, most displacement from thermal contraction occurs due to thermal contraction of the tip. Because the tip dimensions are small, thermal contraction of the tip is minimal.

FIG. 2D shows an example of a specimen holder with a collar 215 and FIG. 2E shows an exploded view of the specimen holder with a collar 215. As shown in FIGS. 2D-2E, in this example, the tip 204 is attached to a thermal connector 216 that provides thermal connectivity to the internal thermal connection section (not shown) in within the section of 203 of the specimen holder. A collar 215 made of a low thermal conductivity material secures the thermal connector 216 rigidly in place at the end of the section 203.

In some embodiments, the collar separates the tip from the outer body of specimen holder so that little thermal contact occurs between the collar and the outer body or between the collar and the tip. In some embodiments, thermal conduction between the collar and the tip can be reduced further by making the contact between them poor. For example, contact can be reduced by roughening the surface of contact (e.g., by sandblasting, or by cutting grooves or thread in the surface), by having only a few points of contact (e.g., by using hard spheres or pins between the collar and outer body), by adding additional intermediate layers with poor contact and thermal conductivity (e.g., fiberglass or polymer films such as PTFE, PEEK, Polyimide), or using spacing barriers. In some embodiments, depending on dimensional constraints, thermal conductance can also be reduced by increasing the length of the thermally insulating collar and reducing its thickness (difference between the outer diameter and inner diameter).

In some embodiments, the tip can be mounted on the low thermal conductance collar and connected to the internal thermal connection section, including a rigid or flexible thermally conducting portion. In some embodiments, thermal conduction between the collar and tip or between the collar and the internal thermal connection section can be reduced further by making the contact between them poor. For example, contact can be reduced by roughening the surface of contact (e.g., by sandblasting, or by cutting grooves or thread in the surface), by having only a few points of contact (e.g., by using hard spheres or pins between the collar and outer body), by adding additional intermediate layers with poor contact and thermal conductivity (e.g., fiberglass or polymer films such as PTFE, PEEK, Polyimide), or using spacing barriers. In some embodiments, thermal conduction between tip and the internal thermal connection (e.g., the rigid portion or the flexible portion) can be maximized by using indium, solder, greases, or welding as described above.

Non-limiting examples of low thermal conductivity materials for a collar include polymers, ceramics, thermoplastics, stainless steel, or glass. Non-limiting examples of ceramics include machinable ceramics, (e.g., Macor). Non-limiting examples of thermoplastics include polyimide (e.g., vespel), and polyesters (e.g., mylar). Non-limiting examples of glasses include Pyrex.

In some embodiments, the combination of specimen holder and cryostat can be used with any cryogen or cooling liquid with a pre-determined boiling/base temperature. Non-limiting examples of cryogens include liquid nitrogen, helium hydrogen, or neon. Helium can provide cooling at temperatures as low as 4 K, or 1.8 K if a pump is used to reduce pressure. Nitrogen can allow cooling at temperatures as low as 77 K. In some embodiments, the pressure can be reduced to reduce the boiling temperature of a cryogenic liquid and thereby reduce the base temperature of the system. Use of a flow or closed-cycle cryostat enables use of helium as a cryogen. In some embodiments, a cryogen can be recycled. For example, by recycling a cryogen, experimental duration can be increased, and the amount of costly cryogen can be reduced. In some embodiments, to recycle cryogen, gas manifold with valves can be used. In some embodiments, a cryogen gas flow meter can be used to connect to a recycling facility.

In some embodiments, the specimen holder includes multiple access ports. In some embodiments, feedthroughs are channeled from the cooling device, allowing thermal sinking from room temperature down to low temperatures. In other embodiments, feedthroughs are channeled from the area near the cold finger. In some embodiments, the access ports channel electrical wires, fiber optics, gases, heat, light, or mechanical motion.

In some embodiments, electrical wires are in connection with sensors, including sensors at the sample tip. Non-limiting examples of sensors include capacitive sensors to measure displacements or strain, for example, in applications where the sample material is strained or stressed. Other non-limiting examples of sensors include force sensors, temperature sensors, and encoders to measure the position of the sample. In some embodiments, electrical wires are in connection with a resistive heater. In one example, electrical wires are used to excite a resistive heater and measure the temperature near the tip of the sample or the sample platform itself (e.g., Si wafer) or to change the temperature of the sample relative to the base temperature achieved by the cryostat. In another example, electrical wires are used to excite a resistive heater on or near the cryostat cold finger top for better temperature regulation of the cold finger. For example, a heater can be located near the cryostat such that it is in thermal contact with the cold finger or can heat the cold finger.

In some embodiments, temperature sensors can be used for temperature control of the specimen holder and sample. For example, one or more sensors mounted at various locations on the specimen holder can provide feedback for temperature control. Any temperature control schemes can be used, including fixed power, on/off, proportional (P), proportional-integral (PI), or proportional-integral-derivative (PID) control.

In some embodiments, one or more temperature sensors measure voltage, resistance, or current through the sensor at a given electrical excitation (e.g., current or voltage). In these embodiments, the measured value (e.g., current or voltage) corresponds to a temperature. In some embodiments, temperature sensors can be mounted using various means to improve thermal contact and accuracy and response. For example, temperature sensors can be mounted by pressing, encasing in thermally conductive compound (e.g., cryogenic grease or epoxy), or pressing an Indium piece (e.g., a washer). Mounting using one of these methods can provide excellent thermal stability at the source of the coldness (e.g., cold finger) and provide long term stability. In some embodiments, the sensitivity and accuracy of the temperature sensors can be matched to the temperature of interest. For example, a temperature sensor can be matched to a temperature of interest by changing the resistance of the material (e.g, platinum), or changing measurement schemes (e.g., using a more sensitive voltmeter or ammeter). In some embodiments a sensor is selected based on the temperature of interest. In some embodiments, platinum sensors are used to sense higher temperatures. In some embodiments, Si diode or RuOx sensors are used for low temperatures. Non-limiting examples of sensors includes Si diode sensors, RuOx sensors, Pt sensors, thermocouples, or a combination thereof.

In some embodiments, temperature control can be achieved by regulating the flow rate of the cryogenic liquid, e.g., using a flow cryostat. In some embodiments, flow rate is regulated by regulating the pressures of a cryogen reservoir. In some embodiments, flow rate is regulated using flow meters. For example, cryogen flow can occur over a long period of time through a transfer line from a large external dewar. This overcomes the issue of holding cold temperature for a long time.

In some embodiments, temperature control is achieved using heaters (e.g., resistive heaters) or a heat load (e.g., warm gas) to control temperature. In some embodiments, heaters or heat loads can be used in addition to regulating flow to control temperature. In some embodiments, heaters can counteract fluctuations in the temperature measured by a temperature sensor. For example, a combination of one or more heaters and one or more sensors placed on or near the cold finger can regulate temperature. For example, a heater or sensor can be located near the cryostat such that it is in thermal contact with the cold finger or can heat the cold finger or accurately measure the temperature of the cold finger. In some embodiments, the resistor of a resistive heater can have extended surface contact with the cold finger to maximize thermal contact. In some embodiments, thermal contact can be increased by using thermal compounds or pressure. Heaters can be mounted using at least the methods describe above to mount sensors. Non-limiting examples of heaters include flexible heaters (e.g., polyimide/Kapton heaters), cartridge heaters, tightly wound heater wire, ceramic heaters, and a combination thereof.

Heaters and sensors can be placed at various portions of the specimen holder for temperature control. For example, heaters and sensors can be placed on or near the cold finger such that they are in thermal contact with the cold finger or can heat the cold finger or accurately measure the temperature of the cold finger. In another example, heaters and sensors can be placed at or near the sample tip such that they are in thermal contact with the sample tip or can heat the sample tip or accurately measure the temperature of the sample tip. Additionally, heaters and sensors can be placed anywhere in between, for example, at any portion of the internal thermal connection section (e.g., the rigid portion or the flexible portion), at thermal connections between components of the specimen holder, or at external portions of the specimen holder. In some embodiments, different sensors can be used for different portions of the specimen holder (e.g., portions that experience different temperatures) depending on desired accuracy, precision, temperature sensitivity, temperature regime of interest, and response to magnetic field for that location. For example, near or at the sample tip, sensors that are insensitive to magnetic fields can be used to avoid interference from or with the magnetic field present in some microscopes (e.g., TEM). In another example, different sensors can be used for different locations, e.g., depending on the temperature at each location. In some embodiments, heaters and sensors can be mounted on the sample carrying chip of the tip, to rapidly change the temperature of the sample without changing the temperature of other portions of the specimen holder. In these embodiments, specialized MEMS sample chips can be used. For example, specialized MEMs sample chips can include an electronic board, wires, or wire bonding. In some embodiments, specialized MEMs chips can be attached using a clamp, a fastener, pressure, spring-loaded pressing, or a combination thereof.

In some embodiments, the specimen holder disclosed herein provides sufficient temperature stability that any temperature fluctuations can be counteracted using temperature control system (e.g., via regulating flow of a cryogen or via heaters). In contrast, systems using a small, open dewar introduce large fluctuations that cannot be compensated for by heaters and sensors. These fluctuations are particularly large when using liquid helium because liquid helium is difficult to handle. Systems using open dewars cannot achieve a sub 5 mK temperature stability and cannot achieve even an about 50-500 mK stability once the dewar runs out. In some embodiments, it was surprisingly found that the specimen holder disclosed herein can achieve much lower, e.g., about 2 mK, temperature stability for long periods of time, e.g., for at least 4 hours or at least 8 hours. In some embodiments, temperature stability is measured at the cold finger during operation of a microscope.

In some embodiments, temperature control (e.g., including heaters or regulating flow of cryogen) can be used to achieve intermediate temperatures between the base temperature and some elevated temperature or between a base temperature and room temperature. For example, a base temperature of about 4 K can be achieved with elevated or intermediate temperatures of 30 K or 110 K. In contrast, in systems using open dewars, it is difficult to achieve intermediate temperatures because increasing temperature causes temperature to fluctuate wildly, and cryogen often runs out before stabilization at a new temperature is achieved. In some embodiments, the specimen holder disclosed herein can hold an intermediate temperature indefinitely. In some embodiments, an intermediate temperature can be achieved by throttling the cryogen flow. In some embodiments, an intermediate temperature can be achieved by activating heaters and sensors to increase the temperature from a base temperature. Additionally, in some embodiments, this temperature stability can also be maintained for many hours.

Because the specimen holder disclosed herein is agnostic to the nature of the cryogen, different cryogens can be used to achieve different temperatures. In some embodiments, the specimen holder can switch between two or more different cryogens to achieve different temperatures. For example, if ultra-low temperature (e.g., liquid helium) is not desired, the sample holder can switch to a different cryogen (e.g., liquid nitrogen) to achieve a more elevated cryogenic temperature. For example, the specimen holder and cryostat are compatible with different cryogens and can be switched to a different cryogen reservoir.

In some embodiments, the specimen holders can achieve temperature stability using any type of cryostat, in addition to flow cryostats. In some embodiments, the specimen holder can be used with a large bath cryostat dewar. For example, because a relatively large bath cryostat dewar can be attached to the specimen holder due to the flexible mechanical decoupling, the temperature stability can be improved by the larger thermal mass of the cryogen and larger frame of liquid cryogen dewar. In some embodiments, valves can be used to pressurize a dewar and keep air out. In some embodiments, a large bath cryostat dewar can create space to include insulation, radiation intercepting insulation/barriers, all of which can maintain cold temperature without rapid fluctuations. In some embodiments, the specimen holder can be used with a closed-cycle cryostat. Likewise, in some embodiments, closed-cycle cryostats can include heaters and sensors for temperature control.

In some embodiments, sensors can be used to monitor vibrations. In some embodiments, vibrations can be monitored during set up of the microscope and sample. In some embodiments, vibrations can be monitored continuously during operation of the microscope, for example during imaging. Vibrations can be monitored in all directions, e.g., vertical vibrations, horizontal vibrations, and a combination thereof. Non-limiting examples of vibration sensors include geophones, MEMS accelerometers, piezoelectric accelerometers, and a combination thereof.

In some embodiments, vibration monitoring can provide feedback to tune the damping, including the choice of material, sequence of damping structures, and rigidity of damping structures or support structures. For example, this approach can be used to tune tension and rigidity of a support structure to a desirable resonant frequency. In some embodiments, vibration monitoring can be used to tune bellows, damping materials, support structures, or a combination thereof, depending on the sources of vibrations. For example, a user can adjust the number of the damping material, the material of the damping material, the angle of the damping material relative to an axis of the specimen holder, or the force applied to the damping material. In some embodiments, the set up (including damping materials and bellows configuration) can be optimized to counteract vibrations typically experienced in the testing environment. For example, vibrations can vary depending on the facility, building, and external conditions. In some embodiments, vibration monitoring can also provide active feedback by providing the vibration measured before and after a flexible interface and feeding that information to an active system to counteracts existing vibrations. For example, an actuator can provide out of phase vibrations to cancel out measured vibrations. Vibration sensors can be placed on the support structure, portions of the cryostat, or portions of the specimen holder (either before or after a flexible interface).

In some embodiments, the access ports channel mechanical motion. In these embodiments, mechanical motion is converted to rotational/tilt motion of the tip on which the sample sits, to allow alignment of the specimen relative the beam of a microscope.

In some embodiments, fiber optics are used to excite the sample with light. For example, semiconductor samples used for optoelectronic applications can be excited with light to observe their properties. In some embodiments, fiber optics can be used to extract light signals emanating from the sample itself. For example, fiber optics can extra light signals from cathodoluminescence or luminescence of the sample.

In some embodiments, gases are used to study adsorption or interactions with the sample. For example, gases can be used to study functional materials for gas capture or catalysis.

In some embodiments, additional access ports are added at any point between the outer holder section, the bellows, and the cryostat. In some embodiments, an access port is located on the cooling device. An access port on the cooling device allows any wires being routed to be thermally sunk more readily from room temperature to the temperature of the cold finger. In some embodiments, an access port is located at the cold finger. An access port at the cold finger accommodates more space for complicated feedthroughs, for example, for mechanical motion. However, an access port at the cold finger can introduce additional heat load to the cold finger. In some embodiments, access ports allow additional vacuum pumping to create a vacuum within the specimen holder, for example, with an external vacuum pump. Use of an external vacuum can accelerate pump down times of the vacuum.

The orientation of the cooling device relative to the specimen holder and via the flexible interface can take various forms. In some embodiments, the cooling device is axially aligned with the section with the sample tip of specimen holder. In some embodiments, an axially aligned configuration does not allow rotation of the holder around its axis if the flexible interface is a bellow because the bellow not have a torsional degree of freedom. In some embodiments, the cooling device can be perpendicular to the section of the specimen holder and suspended. In some embodiments, suspension of the cooling device is accomplished using springs. Suspension provides advantages for vibration isolation by allowing tuning the resonance frequency of the springs. In some embodiments, the cooling device can be angled relative to the section of the specimen holder. In some embodiments, a flexible interface includes series of bellows, rather than a single bellow, in various angles to allow for improved vibration isolation and mechanical compliance (movement and tilt) along various axes. In some embodiments, the orientations take the form of gimbal designs which allow for movement and tilt around various axes.

In some embodiments, any or all of the internal sections are covered by or one more layers of reflective material such as aluminized film (e.g., aluminized mylar) to reduce the radiative heating introduced by warm surfaces of outer sections.

In some embodiments, the outer components of the specimen holder are made of metal, for example, a machinable metal. Non-limiting examples of metals for the outer components of the specimen holder include steel (for example, stainless steel), titanium, brass, aluminum, and combinations thereof.

In one aspect a method of using the specimen holder disclosed herein comprises providing the specimen holder; attaching a sample to the sample tip; aligning the specimen holder with an access port of the microscope; inserting the sample tip into the microscope; cooling the sample to an equilibrium temperature; and imaging the sample using the microscope.

To use the specimen holder disclosed herein, a sample is first attached to the sample tip of the specimen holder. The specimen holder is then aligned with an access port of the microscope. In some embodiments, the specimen holder is aligned using human guidance or translation, for example, using a motorized stage. In some embodiments, the flexible interface is clamped during alignment for ease of manipulation.

The sample tip is then inserted into an access port of the microscope. In some embodiments, a vacuum is formed between the section with the sample tip of the specimen holder and the microscope entrance port, for example, using o-rings, before inserting the sample tip. In some embodiments, a vacuum is formed in the interior of the specimen holder. The vacuum can be formed using either the vacuum of the microscope or a separate vacuum.

The cold finger is then cooled to the equilibrium or base temperature for using the cooling device. The internal thermal connection and sample tip are also cooled to the equilibrium temperature. In embodiments where the cooling device is a flow-cryostat, one end of a transfer line is inserted into the cryostat, the other end of the transfer line is inserted into the large external dewar, and helium flow begins by pressurizing the dewar. In embodiments where the cooling device is a closed-cycle cryostat, a compressor is turned on and refrigeration of the helium gas begins. In embodiments where the cooling device is a bath cryostat, cryogen is transferred into the dewar until it is filled and cold.

In some embodiments, a method of using the specimen holder described herein includes using a flow cryostat, a bath cryostat, or a closed-cycle cryostat to cool to an equilibrium or base temperature. An example achieving a base temperature using each of a flow cryostat, a bath cryostat, and a closed-cycle cryostat is described below.

In some embodiments, a base temperature can be achieved using a flow cryostat. In this example, a base temperature is first achieved after loading the specimen holder and cryostat to the microscope, inserting a transfer line from the cryostat, pressurizing the dewar, and setting the flow rate. The temperature can be monitored and the flow can be controlled or adjusted to achieve a stable temperature (e.g., fluctuations of less than about 5-10 mK) while keeping the flow sufficient. In some embodiments, flow can be controlled manually. In some embodiments, the flow can be controlled with an automatic controller, e.g., based on feedback from a temperature sensor.

In some embodiments, a base temperature can be achieved using a bath cryostat. In this example, a base temperature is first achieved after loading the specimen holder and cryostat to the microscope and filling the bath cryostat with cryogen.

In some embodiments, a base temperature can be achieved using a closed-cycle cryostat. In this example, a base temperature is first achieved after loading the specimen holder and cryostat to the microscope and turning on the compressor associated with the closed-cycle cryostat.

In some embodiments, once the sample reaches the equilibrium or base temperature, it is imaged using the microscope. In some embodiments, one or more stimuli are applied to the sample during imaging. In some embodiment, sensors are used to take additional measurements of the sample during imaging (e.g., temperature sensors, strain sensors).

In some embodiments, after achieving a base temperature (e.g., using a flow cryostat, a bath cryostat, or a closed-cycle cryostat as described above), a temperature control system can be used to control or maintain the temperature. A temperature control system can include one or more heaters and sensors at various locations on the specimen holder to monitor and control temperature. For example, a user can activate the temperature control system. In some embodiments, the temperature control system includes a heater and sensor set to control temperature at the cold finger. For example, a control system (e.g., on/off or PID control) can be used such that the amount of current through a resistive heater depends on feedback from the sensor. In some embodiments, a heater and sensor set at an intermediate position along the length of the internal thermal connection or at the cold finger can also be used be used to control temperature at that location. In some embodiments, a heater and sensor set at the sample tip can be used to control temperature at the sample tip.

### EXAMPLES

Certain embodiments will now be described in the following non-limiting examples.

### Illustrative Sample Holder

In an illustrative specimen holder, shown in FIGS. 1A-1B and 2A-2B, the specimen holder includes six sections.

First, a middle outer section, manifesting as an outer tube 103/203, holds vacuum inside after insertion into the microscope. Various elements can be routed through this evacuated space. The specific dimensions and geometry of the section depend on the physical constraints of the microscope manufacturer.

Second, middle inner section within the outer section 203 which contains at least a rod 213 of made of high thermal conductivity materials in order to extract heat (cool) an end section 204. The inner section can be supported by low thermal conductivity retainer rings 214, pins or other designs whose material and geometry limit the flow of heat from the outer tube. The middle inner section may contain other useful components such as electrical wires, motion rod, sealed gas tubes that are routed towards an end section. The useful components are connected all the way from the tip (sample space) to feedthroughs in the back end that connect to the outside while maintaining a hermetic/vacuum seal. These useful components are addressed externally.

Third, an end section connected to the middle inner section and placed such that it is aligned with the microscope imaging plane. The end section, or tip 104/204, can be a simple plate upon which a specimen is placed. Alternatively, the tip can be more complex and contain electronic boards for accepting electrical wires or multiple hinged part to allow for tilt around the axis perpendicular to the holder axis using actuation from a rod.

Fourth, first front section made of flexible connecting part 102/202 such as flexible bellows under vacuum. The bellows allow for relative motion between the second front section and the middle/end sections. The bellows also allow for vibration isolation by stopping mechanical and acoustic vibrations whose frequency is mismatched to the resonance frequency of the bellows. The bellows can be supported by damping material connecting the two ends of the bellows. The damping material helps reduces the transfer of vibrations.

Fifth, second front section 101/201 made of a device that can provide a cold finger or surface 211. One example of such a device is a flow cryostat, which accepts a cryogenic liquid extracted from a large reservoir, routes it through a heat exchanger and extracts heat from the cold finger. In this example, cryogenic liquid can be drawn by pressurizing a large dewar. Alternatively, the device includes a close-cycle cryostat which uses a mechanical or pneumatic refrigerator of gas vapor to achieve low temperature. These cryostats can take a number of cryogenic liquids, especially helium which is difficult to handle in open containers. These cryostats still suffer from vibration emanating from the flow and boiling of the cryogen through the transfer tube and the cryostat itself.

Sixth, an internal front section which utilizes a flexible connection 212 such as braids, sleeves, springs, or wire bundles to connect the middle inner section to the cold finger 211 of the cryostat 201. This flexible connection allows for a thermal connection while suppressing mechanical coupling. The flexible connection relies on high thermal conductivity materials such as silver, copper or aluminum. The connection is ideally under high vacuum to minimize the effects of gas convection and conduction and accumulation of frost.

### Flexible Interfaces Formed by Bellows

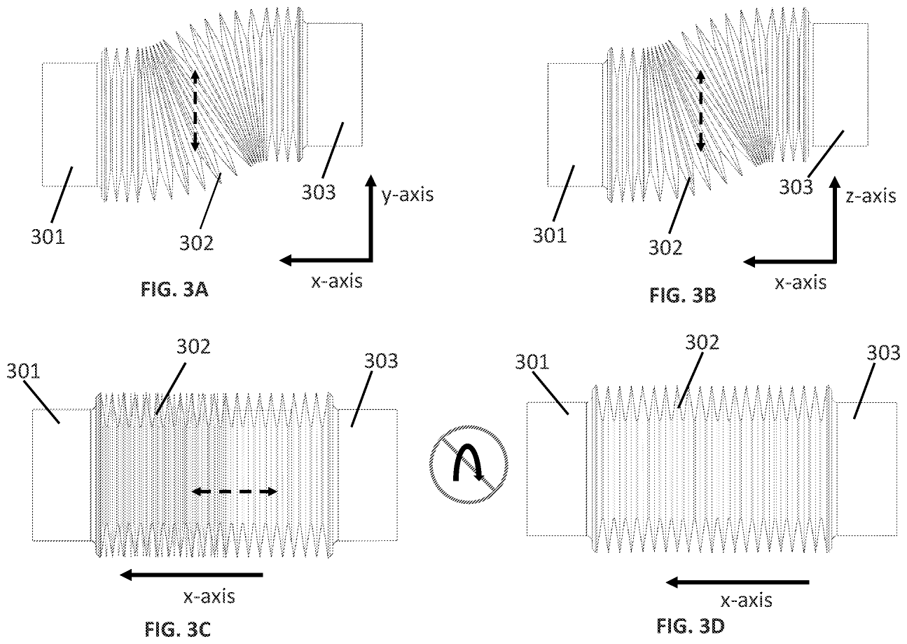

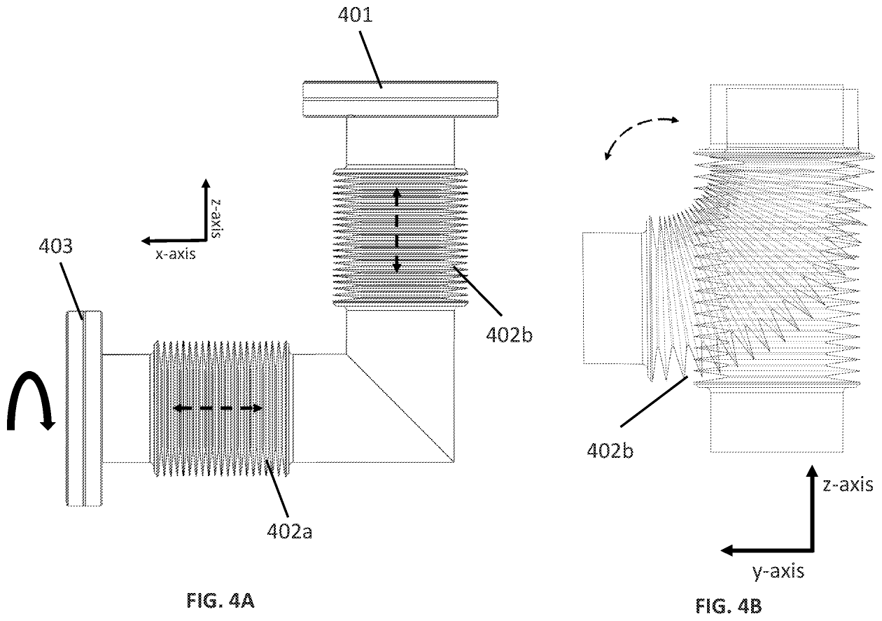

FIGS. 3A-3D and FIGS. 4A-4B show examples of flexible interfaces formed by bellows.

FIGS. 3A-3D show different views of an illustrative single-bellow design. The bellows 302 is fixed to the cryostat 301 on one end and the section with the sample tip (e.g., a tube) 303 on the other end. In this example, the cryostat is aligned axially with the specimen holder. FIGS. 3A-3B show how the bellow can absorb deflection in the y- and z-axes, allowing for the specimen holder tube part to move relative to the cryostat end. The movement in this example is actuated by the microscope's own stage. As shown in FIG. 3A, which provides a view in the x-y plane, the bellows accommodates motion along the y-axis. As shown in FIG. 3B, which provides a view in the x-z plane, the bellows accommodates motion along the z-axis. FIG. 3C shows the mechanical deflection in the x-axis (axial direction of the specimen holder and bellows). As shown in FIG. 3C, the bellows accommodates motion along the x-axis. The grey lines in FIG. 3C show the bellows in a position where the bellows is extended along the x-axis, while the solid black lines show the bellows in a more contracted position. However, as shown in FIG. 3D, the bellows does not accommodate tilt about the x-axis (a torsional degree of freedom, for example, rotation about its axial direction). Since the bellows allow displacement along the x-, y-, and z-axes, it is possible to position the sample within electron microscope, despite its attachment to the cryostat.

FIGS. 4A-4B show a double-bellow system. Such a double-bellows system provides additional degrees of freedom compared to the single-bellows system described above. The grey lines show the bellows in an extended position, while the solid black lines show the bellows in a contracted position. FIG. 4A shows a first bellows 402a with one end fixed to the section with the sample tip (e.g., a tube) 403 of the specimen holder and a second bellows 402b at the other end. The second bellows 402b is fixed to the cryostat interface 401 on the other end. As shown in FIG. 4A, which shows a view in the x-z plane, the first bellows is able to tilt about the x-axis. This is because, as shown in FIG. 4B, which shows a view in the y-z plane, the tilt about the x-axis is absorbed by the second bellow through deflection along the z-axis and y-axis. Since the double-bellows system allows tilt along the x-axis, the specimen holder allows more flexibility in positioning a sample in the electron microscope. It is beneficial to rotate the holder around the x-axis in this way, for example, to align a crystal with the beam or to access different viewing angles of the specimen.

### Flexible Interfaces Formed by Bellows and Damping Material

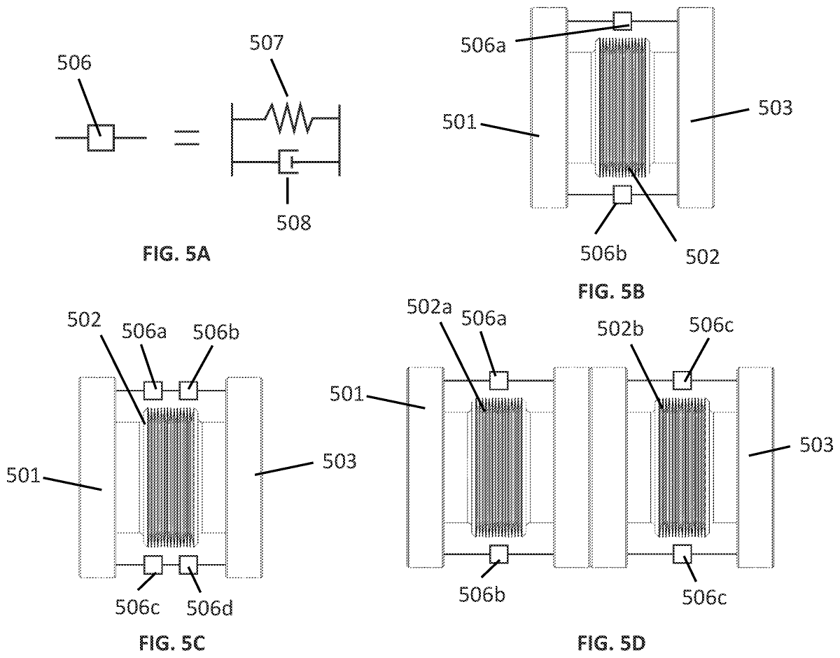

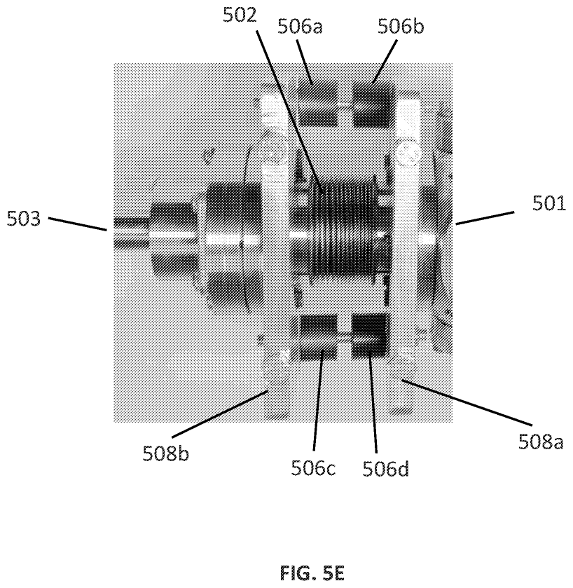

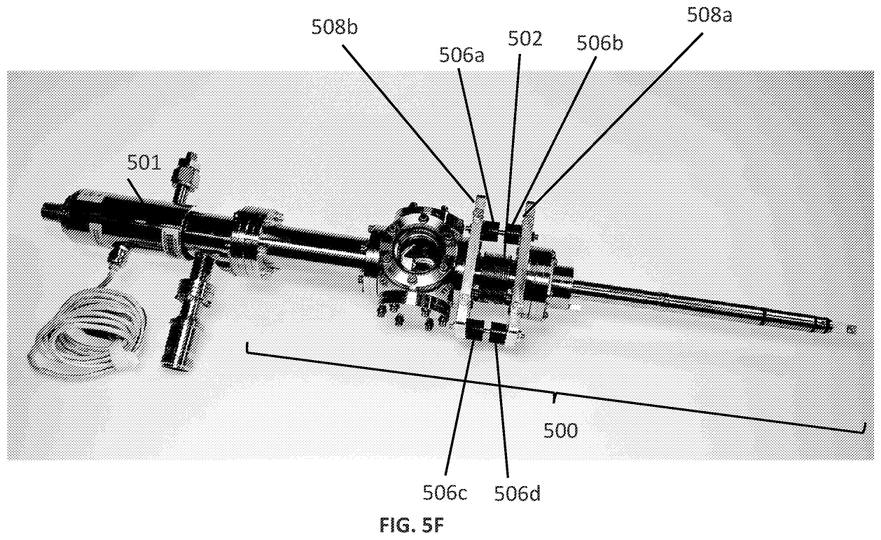

FIGS. 5A-5E show examples of flexible interfaces formed by bellows and a damping material.

FIG. 5A shows a schematic representation of a damping material or damper 506. A damping material, similar to many viscoelastic materials, can be modeled mechanically as a spring 507 and dashpot 508.

FIGS. 5B-5C show examples of interfaces formed by bellows and dampers. In each example, the bellows 502 or set of bellows 502a, 502b are fixed to a cryostat 501 on one end and to the section with the sample tip (e.g., a tube) 503 of the specimen holder on the other end. In this example, the cryostat is aligned axially with the specimen holder.

FIG. 5B shows a schematic of an example of a flexible interface with a bellows 502 and two dampers 506a, 506b arranged in parallel. In this example, the dampers are positioned between the ends of the bellows, which are fixed to the cryostat 501 on one end and the tube 503 of the specimen holder on the other end.

FIG. 5C shows a schematic of an example of a flexible interface with a bellows 502 and four dampers 506a, 506b, 506c, 506d. In this example, there are two sets of dampers arranged in series (506a, 506b in series and 506c, 506d in series) and these sets of dampers are in parallel with each other (506a and 506b in parallel with 506c and 506d). In this example, the dampers are positioned between the ends of the bellows, which are fixed to the cryostat 501 on one end and the tube 503 of the specimen holder on the other end.

FIG. 5D a schematic of shows an example of a flexible interface with two bellows 502a, 502b arranged in series. The first end of the first bellows 502a is fixed to the cryostat 501, and the second end of the first bellows 502a is fixed to the second bellows 502b. The first end of the second bellows 502b is fixed to the first bellows 502a, and the second end of the second bellows 502b is fixed to the tube 503 of the specimen holder. Each bellows includes a pair of dampers arranged in parallel between the ends of the bellows (dampers 506a, 506b for bellows 502a and dampers 506c, 506d for bellows 502b).

FIG. 5E-FIG. 5F show photographs of a flexible interface formed by a bellows and dampers. FIG. 5E shows a photograph of a flexible interface formed by a bellows and dampers. As shown in FIG. 5E, the bellows 502 includes rubber dampers 506a, 506b, 506c, 506d sandwiched between two mounts 508a, 508b, a first mount 508a before the bellows 502 and configured to be fixed to a cryostat 501 and a second mount 508b after the bellows and fixed to the tube 503 of the specimen holder. The rubber dampers in FIG. 5E are arranged in the same way as in the schematic in FIG. 5C. FIG. 5F shows a photograph of a specimen holder 500 with the flexible interface shown in FIG. 5E.

### Support for a Specimen Holder

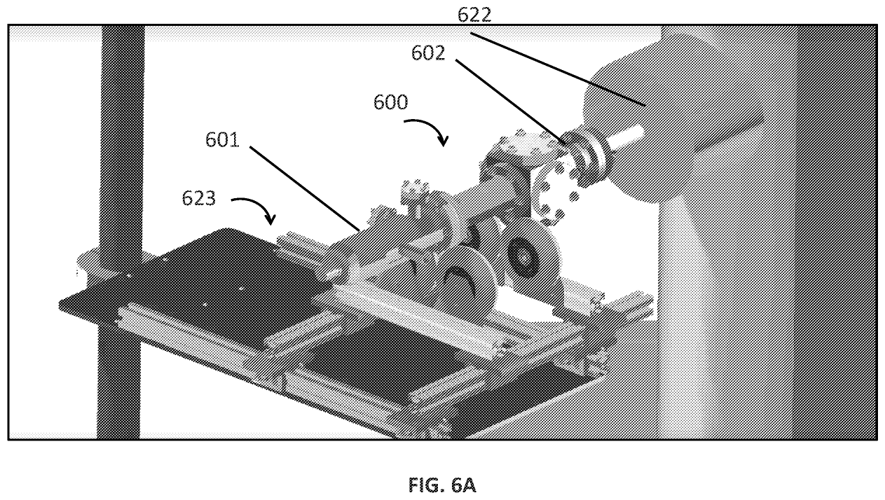

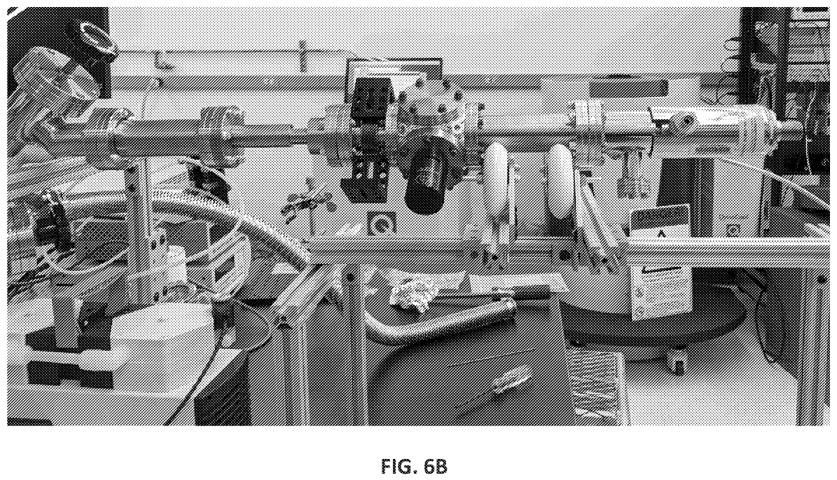

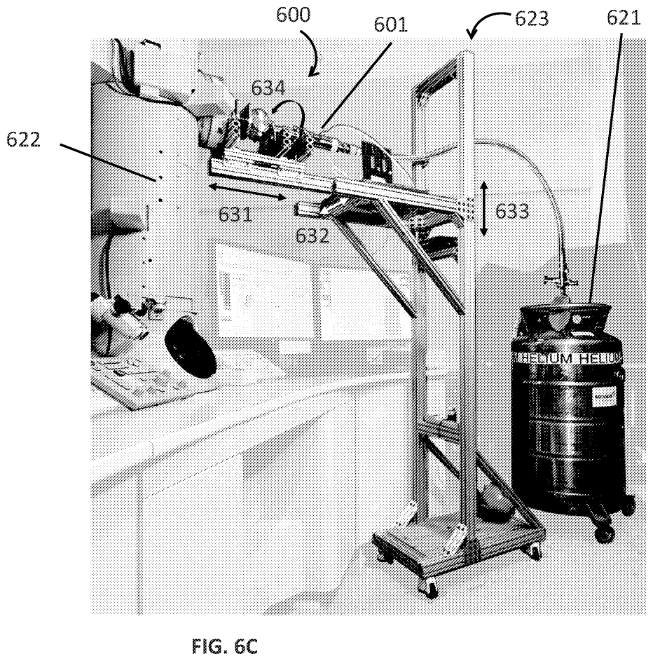

FIGS. 6A-6C show a support 623 for a specimen holder 600. FIG. 6A shows a schematic, while FIGS. 6B-6C show photographs. The support structure in FIGS. 6A-6B includes an XY and rotation table to align and load holder with a microscope 622 and position a sample within the microscope. FIG. 6A shows an illustrative example rendering of the support structure and the assembly being loaded into an electron microscope. The cryostat 601 sits on a support platform. The specimen holder tube is inserted in the stage of the electron microscope 622. This stage can move independently in the x-, y-, z-directions while the cryostat 601 is fixed to the support frame. The deflection is absorbed by the flexible interface/bellows 602. Additional support structures are possible. FIG. 6B shows a prototype assembly loaded into a test high-vacuum chamber.

FIG. 6C shows another example support structure 623 for a specimen holder 600. This support structure provides motion in the x-axis 631, y-axis 632, and z-axis 633, as well as rotational motion about the x-axis 634. These degrees of motion can be used to align the sample with the microscope 622. In this example, the cryostat 601 is attached to a large dewar 621 of liquid helium.

### Using a Specimen Holder

Outside of the microscope, a sample such as a TEM sample is attached to the tip of the sample holder. The specimen holder assembly is then aligned with the access port of the microscope. Using human guidance or a translation (motorized or otherwise) stage, the axis of the holder is aligned with the access port of the microscope. The flexible interface may be clamped during alignment to make it more rigid, so that the whole assembly acts as one rigid unit for ease of manipulation.

A vacuum seal is made by O-rings on the outer section of the holder tube against the microscope entrance port. After pumpdown, the valve into the microscope is opened and the specimen holder assembly is inserted further.

The clamp can then be removed so that now the holder part is mechanically attached to the microscope while the cryostat end is separately supported. Movement of the specimen holder can be actuated using the microscope's own stage, thanks to the mechanical compliance built into the specimen holder.

In the case of the flow-cryostat, one end of a transfer line is inserted into the cryostat. The other end of the transfer line is inserted into the large external dewar. Helium flow begins by pressurizing the dewar. The cold finger begins to cool down. The thermal connection and the tip eventually cool down as well.

In the case of closed-cycle cryostat, a compressor is turned on and refrigeration of the helium gas and hence to cold finger begins. The compressor is preferably in a separate room due to its acoustic noise.

In the case of the bath-cryostat, cryogen is transferred into the dewar until it is filled and cold.

After reaching equilibrium (base temperature), imaging begins. If desired, temperature may be changed (for example, using the heater). Other stimuli may be applied. Various microscopy techniques may be performed depending on the need and microscope instrument. Other beneficial methods may be turned on. For example, the active vibration isolation.

### Cooling Device Oriented Perpendicular to the Tube Section

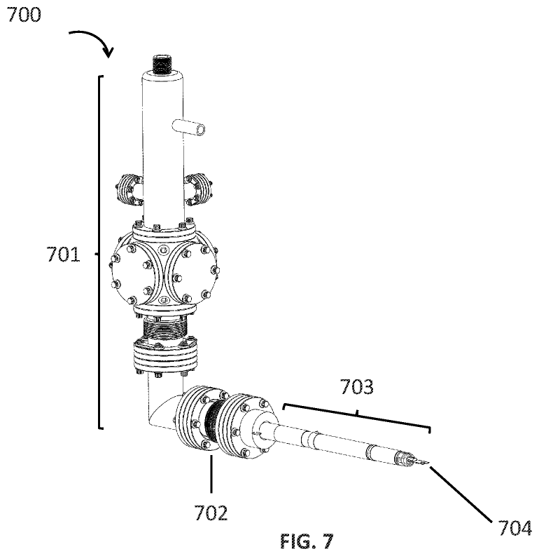

FIG. 7 shows an illustrative specimen holder 700 where the cooling device 701 is aligned perpendicularly with the tube section 703. In this example, the flexible interface 702 is located on the axis of the tube section and the sample tip is at the end of the tube section 704. In this configuration, the cooling device can be supported by a frame or suspended by springs.

### Vibration Monitoring

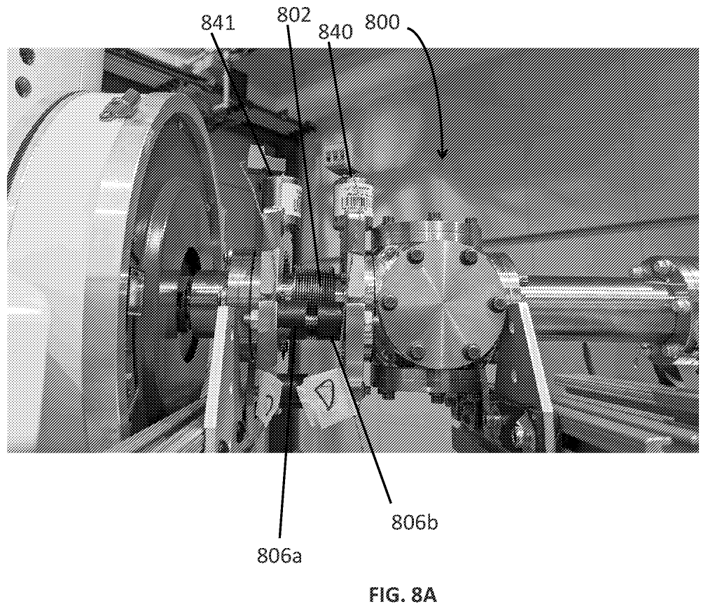

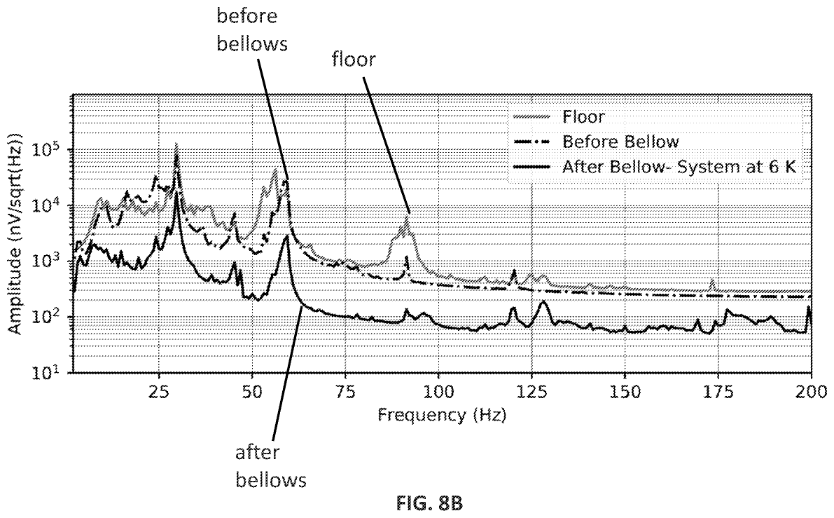

FIGS. 8A-8B show an example of vibration monitoring. FIG. 8A shows the set-up of a specimen holder 800 used for vibration monitoring. In this example, the flexible interface includes a bellows 802 and rubber damping materials 806a, 806b. As shown, in FIG. 8A, vibration was monitored using geophones mounted on the specimen holder at a location before the bellows 840 and at a location after the bellows 841. Vibration was also monitored using a geophone mounted on the floor of the microscope facility. During vibration experiments, the system was at 6K, using a flow cryostat with liquid helium as the cryogen. FIG. 8B shows the amplitude of vibrations as a function of frequency as measured by geophones mounted at the floor, the location before the bellows 840, and at the location after the bellows 841. As shown in FIG. 8B, it was surprisingly found that the amplitude of vibrations was lower at the location after the bellows compared to the amplitude of vibrations measured at the floor and at the location before the bellows. These results show that the flexible interface reduced vibrations after the interface, including at the sample tip.

### Temperature Monitoring

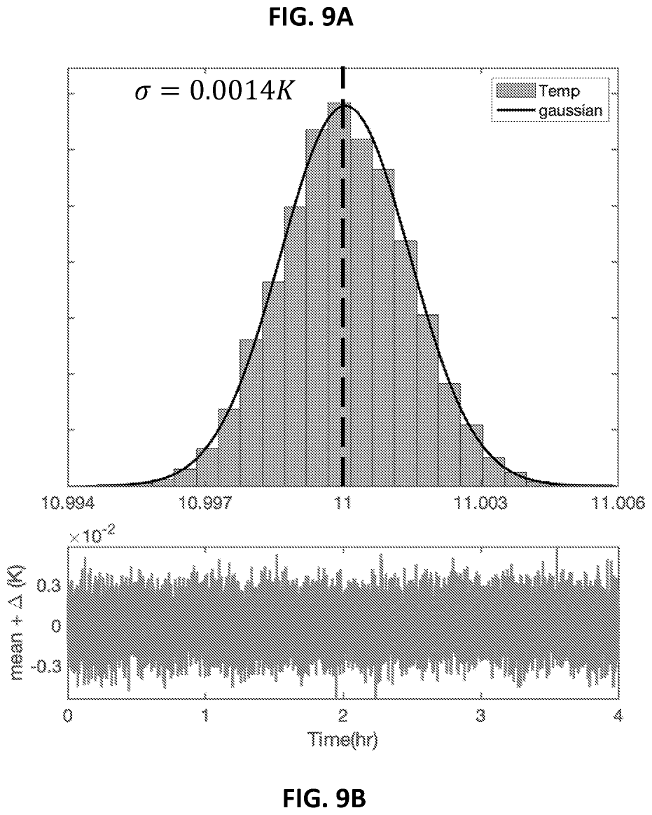

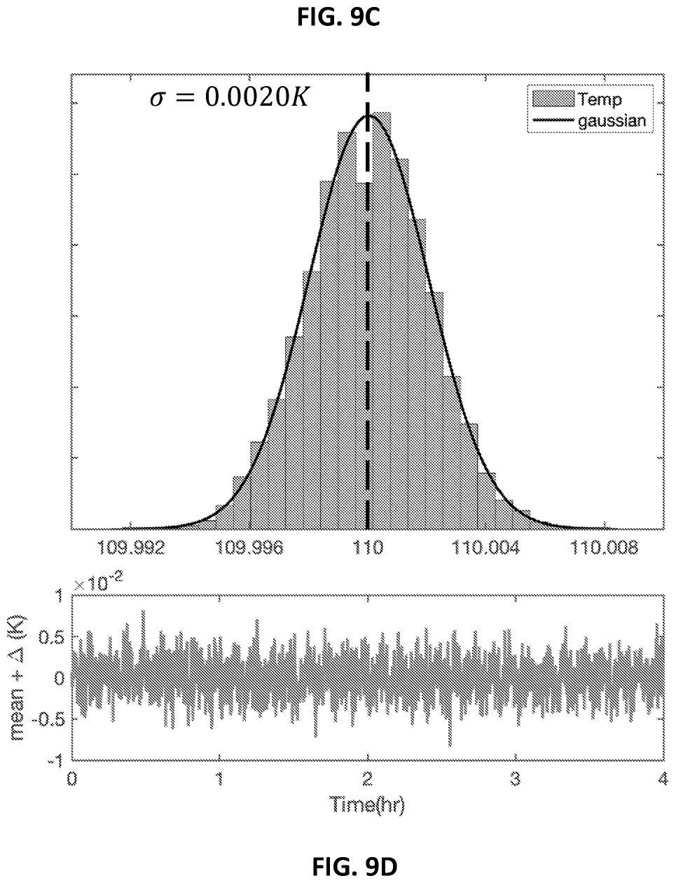

FIGS. 9A-9D show the temperature stability of a specimen holder both at a base temperature (11 K) and at an intermediate temperature (110 K). Temperature stability experiments were performed using a flow cryostat with liquid helium as the cryogen. A Si diode sensor on the cryostat cold finger was used to monitor temperature and provide feedback to regulate flow. FIGS. 9A-9B show temperature stability at a base temperature of 11K, and FIGS. 9C-9D show temperature stability at an intermediate temperature of 110K. The intermediate temperature was achieved using heaters and by reducing flow and pressure from the cryostat. At both temperatures, it was surprisingly found that a temperature stability of about 2 mK was achieved. FIGS. 9A and 9C show a distribution of the measured temperature during the experiment, with the mean temperature indicated with a dashed line and a gaussian distribution indicated with a solid line. At 11K (FIG. 9A), the standard deviation was 0.0014K, and at 110K (FIG. 9C), the standard deviation was 0.0020K. The deviation from the mean over a four hour period is shown in FIG. 9B (9K) and FIG. 9D (110K). As shown in FIGS. 9B and 9D, temperature stability was maintained over a four hour period.

It will be appreciated that while one or more particular materials or steps have been shown and described for purposes of explanation, the materials or steps may be varied in certain respects, or materials or steps may be combined, while still obtaining the desired outcome. Additionally, modifications to the disclosed embodiment and the invention as claimed are possible and within the scope of this disclosed invention.

1-113. (canceled)

114. A specimen holder comprising
a first end configured to attach to a cooling device and a second end configured to be inserted into a microscope;
a section with a sample tip at the second end;
an interface between the first end configured to attach to the cooling device and the section with the sample tip; and
an internal thermal connection section configured to be in thermal contact with a cold finger of the cooling device when the specimen holder is attached to the cooling device and extending through the section with the sample tip to the sample tip.

115. The specimen holder of claim 114, wherein the cooling device is a cryostat.

116. The specimen holder of claim 115, wherein the cryostat is a flow cryostat, a closed-cycle cryostat, or a bath cryostat.

117. The specimen holder of claim 114, wherein the cooling device cools with a cryogenic liquid or a cryogenic gas, and the pressure of the cryogenic liquid or cryogenic gas is increased or decreased compared to atmosphere.

118. The specimen holder of claim 114, wherein the internal thermal connection section comprises a flexible portion.

119. The specimen holder of claim 118, wherein the flexible portion comprises braids, sleeves, springs, wire bundles, straps, or a combination thereof.

120. The specimen holder of claim 118, further comprising netting or thermal insulation material to support the flexible portion of the thermal connection section.

121. The specimen holder of claim 114, further comprising one or more low thermal conductivity rings or pins disposed along the length of the section with the sample tip to support the internal thermal connection section.

122. The specimen holder of claim 114, wherein the interface is a rigid interface.

123. The specimen holder of claim 114, wherein the interface is a flexible interface and comprises a bellows.

124. The specimen holder of claim 123, wherein the flexible interface comprises two or more bellows at an angle relative to each other.

125. The specimen holder of claim 123, wherein the flexible interface comprises two or more bellows in line with each other.

126. The specimen holder of claim 123, further comprising one or more damping materials.

127. The specimen holder of claim 126, wherein the one or more damping materials comprise a viscoelastic material.

128. The specimen holder of claim 126, wherein the one or more damping materials are in parallel with each other.

129. The specimen holder of claim 126, wherein the one or more damping materials are in series with each other.

130. The specimen holder of claim 126, wherein the flexible interface comprises two or more damping materials with different resonant frequencies.

131. The specimen holder of claim 123, wherein the flexible interface allows displacement along at least one of the x-axis, y-axis, and z-axis.

132. The specimen holder of claim 1, wherein the specimen holder is configured to attach to the cooling device such that the cooling device is aligned at an angle relative to the section with the sample tip.

133. The specimen holder of claim 114, wherein the interior of the specimen holder is configured to be under a vacuum.

134. The specimen holder of claim 114, further comprising at least one access port, wherein the access ports provide access for at least one of electrical wires, fiber optics, gas, heat, and mechanical motion.

135. The specimen holder of claim 114, further comprising a temperature sensor located near the sample tip.

136. The specimen holder of claim 135, wherein the temperature sensor is located near or at the cold finger when the specimen holder is attached to the cooling device.

137. The specimen holder of claim 135, wherein the temperature sensor is configured to provide feedback for temperature control.

138. The specimen holder of claim 137, wherein temperature control is provided by regulating flow of a cryogenic liquid or a cryogenic gas.

139. The specimen holder of claim 137, wherein temperature control is provided by a heater.

140. The specimen holder of claim 114, further comprising a heater located near or at the cold finger when the specimen holder is attached to the cooling device.

141. The specimen holder of claim 114, wherein the specimen holder is configured to maintain a temperature stability of less than about 5 mK.

142. The specimen holder of claim 114, further comprising a vibration sensor configured to provide feedback for vibration control.

143. The specimen holder of claim 114, wherein the sample tip comprises a board to allow electrical contact with the sample.

144. The specimen holder of claim 114, wherein one or more portions of the specimen holder are covered by one or more layers of a reflective material.

145. The specimen holder of claim 114, wherein the specimen holder is configured to position the sample tip in the microscope.

146. A system comprising the specimen holder of claim 114, further comprising a support fixed to the cooling device, the support resting on a vibration isolation structure.

147. The system of claim 146, wherein the vibration isolation structure is selected from the list consisting of optical tables, eddy-current-damped platforms, negative stiffness isolators, pneumatic isolators, and a combination thereof.

148. The system of claim 146, wherein the support is configured to be anchored to a heavy mass.

149. The system of claim 146, wherein the support is configured to be anchored to the microscope.

150. The system of claim 146, wherein the support is configured to displace the specimen holder along at least one of the x-axis, y-axis, and z-axis.

151. The system of claim 146, wherein the support is covered with a sound absorbing or a sound reflecting material.

152. A method comprising
providing a specimen holder comprising,
a first end configured to attach to a cooling device and a second end configured to be inserted into a microscope;
a section with a sample tip at the second end;
an interface between the first end configured to attach to the cooling device and the section with the sample tip; and
an internal thermal connection section configured to be in thermal contact with a cold finger of the cooling device when the specimen holder is attached to the cooling device and extending through the section with the sample tip to the sample tip;
attaching a sample to the sample tip;
aligning the specimen holder with an access port of the microscope;
inserting the sample tip into the microscope;
cooling the sample to a base temperature; and
imaging the sample using the microscope.
